(19) United States
(12) Patent Application Publication
(10) Pub. No.: US 2010/0055320 A1
(43) Pub. Date: Mar. 4, 2010

(54) FILM DEPOSITION APPARATUS, SUBSTRATE PROCESSING APPARATUS, FILM DEPOSITION METHOD AND STORAGE MEDIUM

(75) Inventor: MANABU HONMA, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/552,339

(22) Filed: Sep. 2, 2009

(30) Foreign Application Priority Data
Sep. 4, 2008 (JP) 2008-227032
Aug. 4, 2009 (JP) 2009-181807

(51) Int. Cl. C23C 16/458; C23C 16/00

(52) U.S. Cl. 427/255.28; 118/730; 118/696

(57) ABSTRACT

A film deposition apparatus includes a turntable rotatably provided in a chamber. First and second reaction gas supplying portions supply first and second reaction gases to one surface of the turntable, respectively. A separation gas is discharged from a separation gas supplying portion to a separation area between a first process area to which the first reaction gas is supplied and a second process area to which the second reaction gas is supplied. A ceiling surface is provided in the separation area to form a thin space between the turntable to allow the separation gas flowing from the separation area to a process area side. An elevation mechanism to move the substrate upward and downward is provided in a substrate placement part. The elevation mechanism is movable in upward and downward directions relative to the turntable and movable in a radial direction of the turntable.

### CROSS-REFERENCE TO RELATED APPLICATIONS

This application is based upon and claims the benefit of priority of the prior Japanese Patent Applications No. 2008-227032, filed on Sep. 4, 2008, and No. 2009-181807, filed Aug. 4, 2009, the entire contents of which are incorporated herein by reference.

### FIELD OF THE INVENTION

The present invention relates to a film deposition apparatus, a substrate processing apparatus and a film deposition method, which forms a thin film in which a reaction product is laminated, by repeatedly performing a cycle to sequentially supply two kinds of reaction gases, which react with each other, onto a surface of a substrate, and a storage medium storing a program for performing the film deposition method.

### BACKGROUND ART

As a film deposition technique in a semiconductor fabrication process, there has been known a so-called Atomic Layer Deposition (ALD) or Molecular Layer Deposition (MLD). In such a film deposition technique, a first reaction gas is adsorbed on a surface of a semiconductor wafer (referred to as a wafer hereinafter) under vacuum and then a second reaction gas is adsorbed on the surface of the wafer in order to form one or more atomic or molecular layers through reaction of the first and the second reaction gases on the surface of the wafer; and such an alternating adsorption of the gases is repeated plural times, thereby depositing a film on the wafer. This technique is advantageous in that the film thickness can be controlled at higher accuracy by the number of times alternately supplying the gases, and in that the deposited film can have excellent uniformity over the wafer. Therefore, this deposition method is thought to be promising as a film deposition technique that can address further miniaturization of semiconductor devices.

Such a film deposition method may be preferably used, for example, for depositing a dielectric material to be used as a gate insulator. When silicon dioxide (SiO₂) is deposited as the gate insulator, a bis (tertiary-butylamino) silane (BTBAS) gas or the like is used as a first reaction gas (source gas) and ozone gas or the like is used as a second gas (oxidation gas).

In order to carry out such a deposition method, use of a single-wafer deposition apparatus having a vacuum chamber and a shower head at a top center portion of the vacuum chamber has been under consideration. In such a deposition apparatus, the reaction gases are introduced into the chamber from the top center portion, and unreacted gases and by-products are evacuated from a bottom portion of the chamber. When such a deposition chamber is used, it takes a long time for a purge gas to purge the reaction gases, resulting in an extremely long process time because the number of cycles may reach several hundred. Therefore, a deposition method and apparatus that enable high throughput is desired.

Under these circumstances, film deposition apparatuses having a vacuum chamber and a turntable that holds plural wafers along a rotation direction have been proposed.

Patent Document 1 listed below discloses a deposition apparatus whose process chamber is shaped into a flattened cylinder. The process chamber is divided into two half circle areas. Each area has an evacuation port provided to surround the area at the top portion of the corresponding area. In addition, the process chamber has a gas inlet port that introduces separation gas between the two areas along a diameter of the process chamber. With these configurations, while different reaction gases are supplied into the corresponding areas and evacuated from above by the corresponding evacuation ports, a turntable is rotated so that the wafers placed on the turntable can alternately pass through the two areas. A separation area to which the separation gas is supplied has a lower ceiling than the areas to which the reaction gases are supplied.

Patent Document 2 discloses a process chamber having a wafer support member (turntable) that holds plural wafers and that is horizontally rotatable, first and second gas ejection nozzles that are located at equal angular intervals along the rotation direction of the wafer support member and oppose the wafer support member, and purge nozzles that are located between the first and the second gas ejection nozzles. The gas ejection nozzles extend in a radial direction of the wafer support member. A top surface of the wafers is higher than a top surface of the wafer supporting member, and the distance between the ejection nozzles and the wafers on the wafer support member is about 0.1 mm or more. A vacuum evacuation apparatus is connected to a portion between the outer edge of the wafer support member and the inner wall of the process chamber. According to a process chamber so configured, the purge gas nozzles discharge purge gases to create a gas curtain, thereby preventing the first reaction gas and the second reaction gas from being mixed.

Patent Document 3 discloses a process chamber that is divided into plural process areas along the circumferential direction by plural partitions. Below the partitions, a circular rotatable susceptor on which plural wafers are placed is provided leaving a slight gap in relation to the partitions. In addition, at least one of the process areas serves as an evacuation chamber.

Patent Document 4 discloses a process chamber having four sector-shaped gas supplying plates each of which has a vertex angle of 45 degrees, the four gas supplying plates being located at angular intervals of 90 degrees, evacuation ports that evacuate the process chamber and are located between the adjacent two gas supplying plates, and a susceptor that holds plural wafers and is provided in order to oppose the gas supplying plate. The four gas supplying plates can discharge AsH₃ gas, H₂ gas, trimethyl gallium (TMG) gas, and H₂ gas, respectively.

Patent Document 5 discloses a process chamber having a circular plate that is divided into four quarters by partition walls and has four susceptors respectively provided in the four quarters, four injector pipes connected into a cross shape, and two evacuation ports located near the corresponding susceptors. In this process chamber, four wafers are mounted in the corresponding four susceptors, and the four injector pipes rotate around the center of the cross shape above the circular plate while ejecting a source gas, a purge gas, a reaction gas, and another purge gas, respectively. An injector unit is rotated horizontally and vacuum exhaust is performed from a periphery of a turntable so that injector pipes are positioned sequentially in the four placement areas.

Furthermore, Patent Document 6 (Patent Documents 7, 8) discloses a film deposition apparatus preferably used for an Atomic Layer CVD method that causes plural gases to be alternately adsorbed on a target (a wafer). In the apparatus, a susceptor that holds the wafer is rotated, while source gases and purge gases are supplied to the susceptor from above. Paragraphs 0023, 0024, and 0025 of the document describe partition walls that extend in a radial direction from a center of a chamber, and gas ejection holes that are formed in a bottom of the partition walls in order to supply the source gases or the purge gas to the susceptor, so that an inert gas as the purge gas ejected from the gas ejection holes produces a gas curtain. Regarding evacuation of the gases, paragraph 0058 of the document describes that the source gases are evacuated through an evacuation channel 30a, and the purge gases are evacuated through an evacuation channel 30b.

Patent Document 9 discloses lift pins for placing a substrate such as a wafer in a substrate placement area formed on a susceptor of a film deposition apparatus. The lift pins have an upward and downward driving mechanism so that the substrate such as a wafer is placed in the substrate placement area by the upward and downward movement by the drive mechanism.

Patent Document 1: U.S. Pat. No. 7,153,542 (FIGS. 6A, 6B)

Patent Document 2: Japanese Patent Application Laid-Open Publication No. 2001-254181 (FIGS. 1, 2)

Patent Document 3: Japanese Patent Publication No. 3,144,664 (FIGS. 1, 2, claim 1)

Patent Document 4: Japanese Patent Application Laid-Open Publication No. H4-287912

Patent Document 5: U.S. Pat. No. 6,634,314

Patent Document 6: Japanese Patent Application Laid-Open Publication No. 2007-247066 (paragraphs 0023 through 0025, 0058, FIGS. 12 and 13)

Patent Document 7: United States Patent Publication No. 2007-218701

Patent Document 8: United States Patent Publication No. 2007-218702

Patent Document 9: U.S. Pat. No. 6,646,235

However, in the apparatus disclosed in Patent Document 1, because the reaction gases and the separation gas are supplied downward and then evacuated upward from the evacuation ports provided at the upper portion of the chamber, particles in the chamber may be blown upward by the upward flow of the gases and fall on the wafers, leading to contamination of the wafers.

In the technique disclosed in Patent Document 2, the gas curtain cannot completely prevent mixture of the reaction gases but may allow one of the reaction gases to flow through the gas curtain to be mixed with the other reaction gas partly because the gases flow along the rotation direction due to the rotation of the wafer support member. In addition, the first (second) reaction gas discharged from the first (second) gas outlet nozzle may flow through the center portion of the wafer support member to meet the second (first) gas, because centrifugal force is not strongly applied to the gases in a vicinity of the center of the rotating wafer support member. Once the reaction gases are mixed in the chamber, an MLD (or ALD) mode film deposition cannot be carried out as expected.

In the apparatus disclosed in Patent Document 3, in a process chamber, process gas introduced into one of the process areas may diffuse into the adjacent process area through the gap below the partition, and be mixed with another process gas introduced into the adjacent process area. Moreover, the process gases may be mixed in the evacuation chamber, so that the wafer is exposed to the two process gases at the same time. Therefore, ALD (or MLD) mode deposition cannot be carried out in a proper manner by this process chamber.

The disclosure of Patent Document 4 does not provide any realistic measures to prevent two source gases (AsH₃, TMG) from being mixed. Because of the lack of such measures, the two source gases may be mixed around the center of the susceptor and through the H₂ gas supplying plates. Moreover, because the evacuation ports are located between the adjacent two gas supplying plates to evacuate the gases upward, particles are blown upward from the susceptor surface, which leads to wafer contamination.

In the process chamber disclosed in Patent Document 5, after one of the injector pipes passes over one of the quarters, this quarter cannot be purged by the purge gas in a short period of time. In addition, the reaction gas in one of the quarters can easily flow into an adjacent quarter. Therefore, it is difficult to perform an MLD (or ALD) mode film deposition.

According to the technique disclosed in Patent Document 6, source gases can flow into a purge gas compartment from source gas compartments located in both sides of the purge gas compartment and be mixed with each other in the purge gas compartment. As a result, a reaction product is generated in the purge gas compartment, which may cause particles to fall onto the wafer.

When performing a film deposition method in the film deposition apparatus disclosed in Patent Documents 1 through 5, because a rotation table or turntable has a large diameter to permit a plurality of wafers such as, for example, four to six sheets, placed thereon in circular arrangement, an inertial force (hereinafter, referred to as inertia) of the turntable is large. Thus, if a method of driving the turntable by a stepping motor via a belt drive, which is a turntable driving method usually used in a film deposition apparatus in which a film deposition is carried out in a vacuum chamber, the turntable slips relative to the motor during acceleration and deceleration, which results in an angular displacement of an actual rotational angle with respect to a rotational angle instructed to the motor. Hereinafter, such an angular displacement in a rotational angle is referred to as a loss of synchronism. Although a motor for driving the turntable and a power transmission method are not disclosed in Patent Documents 1 through 5, in a method of driving a turntable by a stepping motor via a belt drive, which method is generally used in a film deposition apparatus using a vacuum chamber, because the inertia of the turntable is large, a slip (displacement) in rotational angles is generated between the turntable and a motor shaft due to a slip or a stretch of the belt at a time of start or at a time stop, which results in a loss of synchronism. As a result, when carrying a substrate into or out of a vacuum pump, there may occur a problem in that the substrate cannot be placed on the turntable with good positional accuracy or the substrate cannot be taken out of the turntable surely.

With the technique disclosed in Patent Document 9, because the substrate placement area is normally formed larger than the substrate such as a wafer, the substrate such as a wafer moves in the substrate placement area due to a centrifugal force when the susceptor is rotated, and the substrate may be damaged due to a contact of the substrate with a wall surface of the substrate placement area.

### SUMMARY OF THE INVENTION

It is a general object of the present invention to provide a novel, improved and useful film deposition apparatus, substrate processing apparatus, film deposition method, and a storage medium storing a program for performing the film deposition method, in which the above-mentioned problem is eliminated.

A more specific object of the present invention is to prevent generation of defective products by preventing a substrate, on which a film is deposited, from cracking or chipping, and to enable a film deposition being performed under a clean environment.

In order to achieve the above-mentioned object, there is provided according to one aspect of the present invention a film deposition apparatus for depositing a film on a substrate by carrying out a cycle of alternately supplying at least two kinds of reaction gases that react with each other to the substrate to produce a layer of a reaction product in a chamber, the film deposition apparatus comprising: a turntable rotatably provided in the chamber; a substrate placement part provided in one surface of the turntable and configured to place the substrate thereon; a first reaction gas supplying portion configured to supply a first reaction gas to the one surface; a second reaction gas supplying portion configured to supply a second reaction gas to the one surface, the second reaction gas supplying portion being separated from the first reaction gas supplying portion along a rotation direction of the turntable; a separation area located along the rotation direction between a first process area to which the first reaction gas is supplied and a second process area to which the second reaction gas is supplied, the separation area separating the first process area and the second process area from each other; a center area that is located substantially in a center portion of the chamber in order to separate the first process area and the second process area, and has an discharge hole that discharges a first separation gas along the one surface; and an evacuation port provided, configured, and arranged to exhaust the first and second reaction gases together with the separation gas diffusing both sides of the separation area and the separation gas discharged from the center portion; a separation gas supplying portion provided in the separation area to supply the separation gas; a ceiling surface provided in the separation area and located on both sides of the separation gas supplying portion, the ceiling surface forming a thin space between the turntable to allow the separation gas flowing from the separation area to a process area side; and an elevation mechanism provided in the substrate placement part to move the substrate upward and downward, wherein the elevation mechanism is movable upward and downward relative to the turntable and is also movable in a radial direction of the turntable.

Additionally, there is provided according to another aspect of the present invention a film deposition apparatus for depositing a film on a substrate by carrying out a cycle of alternately supplying at least two kinds of reaction gases that react with each other to the substrate to produce a layer of a reaction product in a chamber, the film deposition apparatus comprising: a turntable rotatably provided in the chamber; a plurality of substrate placement parts provided in the turntable to place a plurality of pieces of the substrate along the same circumference of circle of the turntable; a first reaction gas supplying portion configured to supply a first reaction gas, the first reaction gas provided on a side where the substrate placement parts are formed in the chamber; a second reaction gas supplying portion configured to supply a second reaction gas supplying portion, the second reaction gas supplying portion provided at a position distant from the first reaction gas supplying portion on the side where the substrate placement parts are formed in the chamber; a first separation gas supplying portion configured to supply a first separation gas, the first separation gas supplying portion provided between a first process area to which the first reaction gas is supplied by the first reaction gas supplying portion and a second process area to which the second reaction gas is supplied by the second reaction gas supplying portion to separate the first process area and the second process area from each other; a conveyance port provided on a side wall of the chamber to convey the substrate from an outside of the chamber into an inside of the chamber, the conveyance port being opened and closed by a gate valve; and a substrate holding arm for conveying the substrate through the conveyance port, wherein the substrate holding arm includes two rod-shaped holding parts, one of the rod-shaped holding parts being provided with at least one substrate holding portion and the other of the rod-shaped holding parts being provided with at least two substrate holding portions to hold the substrate.

Further, there is provided according to another aspect of the present invention a substrate processing apparatus comprising: a vacuum transfer chamber in which a substrate transfer part is arranged; the above-mentioned film deposition apparatus connected airtightly to the vacuum transfer chamber; and a preliminary vacuum chamber airtightly connected to the vacuum transfer chamber, a pressure inside the preliminary vacuum chamber being changed between an atmospheric pressure and a vacuum pressure.

Additionally, there is provided according to another aspect of the present invention a film deposition method for forming a film on a substrate by carrying out a plurality of cycles of sequentially supplying at least two kinds of reaction gases that react with each other to a surface of the substrate: conveying the substrate from an outside of a vacuum chamber through a conveyance port, and placing the substrate at a position most apart from a center of the turntable in a substrate placement part provided for placing the substrate on the turntable of the vacuum chamber; rotating the turntable; and depositing the film on the substrate by supplying first and second reaction gases to a surface of the turntable in which a substrate placement part is formed from a first reaction gas supplying portion and a second reaction gas supplying portion provided separate from each other in the vacuum chamber, and supplying a separation gas from a separation gas supplying portion provided between the first reaction gas supplying portion and the second reaction gas supplying portion.

Additionally, there is provided according to a further aspect of the present invention a film deposition method for forming a film on a substrate by carrying out a plurality of cycles of sequentially supplying at least two kinds of reaction gases that react with each other to a surface of the substrate: placing the substrate on an elevation mechanism provided in a substrate placement part formed as a concave portion on a turntable, the substrate being conveyed from an outside of a vacuum chamber into an inside of the vacuum chamber through a conveyance port; after moving the substrate into the concave portion, causing the substrate to contact or position close to a wall surface of the concave portion by moving the elevation mechanism in a radial direction of the turntable; after moving the elevation mechanism in a radial direction of the turntable, moving the elevation mechanism downward and placing the substrate on a bottom surface of the concave portion; after placing the substrate on a bottom surface of the concave portion, rotating the turntable; and depositing the film on the substrate by supplying first and second reaction gases to a surface of the turntable in which the substrate placement part is formed from first and second reaction gas supplying portions provided separate from each other in the vacuum chamber, and supplying a separation gas from a separation gas supplying portion provided between the first reaction gas supplying portion and the second reaction gas supplying portion.

There is provided according to yet another aspect of the present invention a film deposition method for forming a film on a substrate by carrying out a plurality of cycles of sequentially supplying at least two kinds of reaction gases that react with each other to a surface of the substrate: conveying the substrate to a position directly above a substrate placement part formed on a turntable as a concave portion to place the substrate thereon by a substrate holding arm having two rod-shaped holding parts for holding the substrate, one of the rod-shaped holding parts having at least one substrate holding portion and the other of the rod-shaped holding parts having at least two substrate holding portions; after conveying the substrate to a position directly above the substrate placement part, moving the substrate to a position lower than a surface of the turntable by moving the substrate holding arm downward; after moving the substrate holding arm downward, causing the substrate to contact or move to a position close to a wall surface of the concave portion by moving the substrate holding arm in a radially outward direction of the turntable; after causing the substrate to contact or move to a position close to a wall surface of the concave portion, moving the substrate holding arm downward until the substrate contacts a bottom surface of the concave portion; after moving the substrate holding arm downward, rotating the turntable; and depositing the film on the substrate by supplying first and second reaction gases to a surface of the turntable in which the substrate placement part is formed from first and second reaction gas supplying portions provided separate from each other in the vacuum chamber, and supplying a separation gas from a separation gas supplying portion provided between the first reaction gas supplying portion and the second reaction gas supplying portion.

According to the present invention, when forming a thin film by laminating layers of a reaction product by sequentially supplying a plurality of reaction gases, which reacts with each other, onto a surface of the substrate, the substrate on which the film is deposited can be prevented from cracking or chipping. Thereby, generation of defective products is prevented and generation of particles is prevented, which enables a film deposition being performed under a clean environment. Therefore, contamination is suppressed as much as possible, and a film deposition of a high quality thin film without mixture of impurities can be achieved.

Other objects, features and advantages of the present invention will become more apparent from the following detailed description when read in conjunction with the accompanying drawings.

### BRIEF DESCRIPTION OF THE DRAWINGS

FIG. 1 is a vertical cross-sectional view of a film deposition apparatus according to an embodiment of the present invention;

FIG. 2 is a perspective view illustrating an outline structure of an interior of the film deposition apparatus;

FIG. 3 is a horizontal plan view of the film deposition apparatus;

FIGS. 4A and 4B are vertical cross-sectional views illustrating a process area and a separation area in the film deposition apparatus;

FIG. 5 is a vertical cross-sectional view illustrating a part of the film deposition apparatus;

FIG. 6 is a partially cut-away perspective view of the film deposition apparatus;

FIG. 7 is an illustration illustrating flows of a separation gas or a purge gas;

FIG. 8 is a partially cut-away perspective view of the film deposition apparatus;

FIG. 9 is an illustrative cross-sectional view of a turntable of the film deposition apparatus;

FIGS. 10A through 10D are illustrative cross-sectional views illustrating a procedure of placing a wafer on the turntable of the film deposition apparatus;

FIG. 11 is a plan view of a state where the wafer is placed on the turntable;

FIG. 12 is an illustration illustrating a condition of a first reaction gas and a second reaction gas being separated by a separation gas and exhausted;

FIG. 13A is a plan view for explaining dimensions of a concave portion used for the separation area;

FIG. 13B is a cross-sectional view for explaining dimensions of a concave portion used for the separation area;

FIG. 14 is a vertical cross-sectional view illustrating another example of the separation area;

FIGS. 15A though 15C are vertical cross-sectional views illustrating other examples of the concave portion used for the separation area;

FIGS. 16A through 16G are bottom views illustrating other examples of gas discharge holes of a reaction gas supply part;

FIG. 17 is a plan view illustrating a film deposition apparatus according to another embodiment;

FIG. 18 is a plan view illustrating a film deposition apparatus according a further embodiment of the present invention;

FIG. 19 is a perspective view illustrating an outline structure of an interior of the film deposition apparatus according the further embodiment of the present invention;

FIG. 20 is a plan view illustrating a film deposition apparatus according to yet another embodiment of the present invention;

FIG. 21 is a cross-sectional view illustrating the film deposition apparatus according to yet another embodiment of the present invention;

FIGS. 22A through 22D are illustrative cross-sectional views illustrating a procedure of placing the wafer on the turntable;

FIGS. 23A and 23B are illustrative cross-sectional views illustrating a procedure of placing the wafer on the turntable;

FIG. 24 is an illustrative cross-sectional view of the turntable having another structure in the film deposition apparatus; and

FIG. 25 is an illustrative plan view illustrating an example of a substrate processing system using the film deposition apparatus according to the present invention.

### DETAILED DESCRIPTION OF THE PREFERRED EMBODIMENTS

A description will now be given, with reference to the drawings, of embodiments of the present invention.

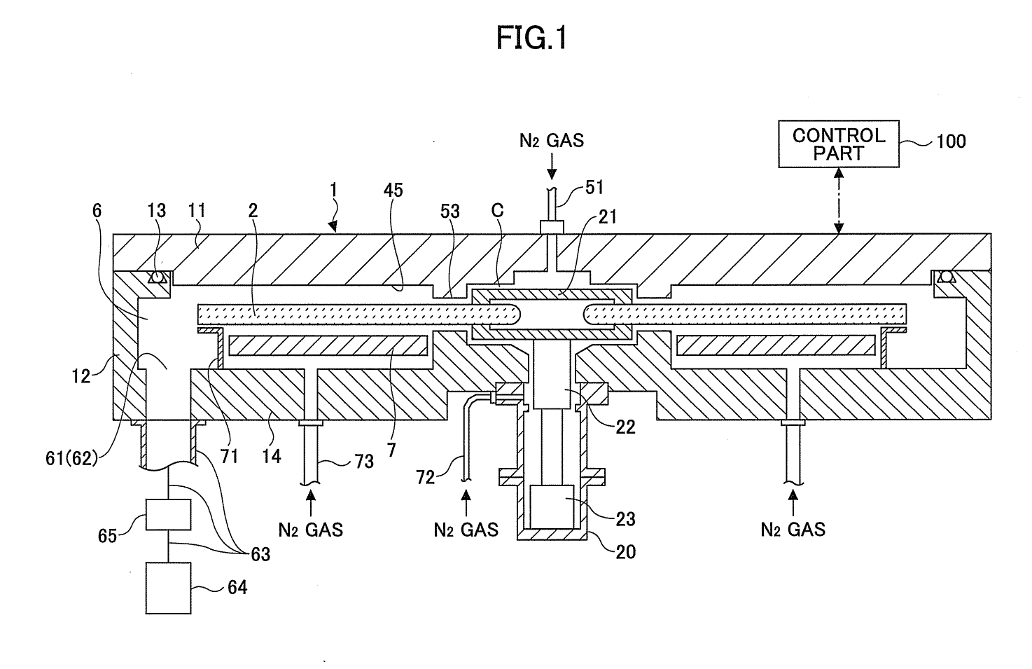

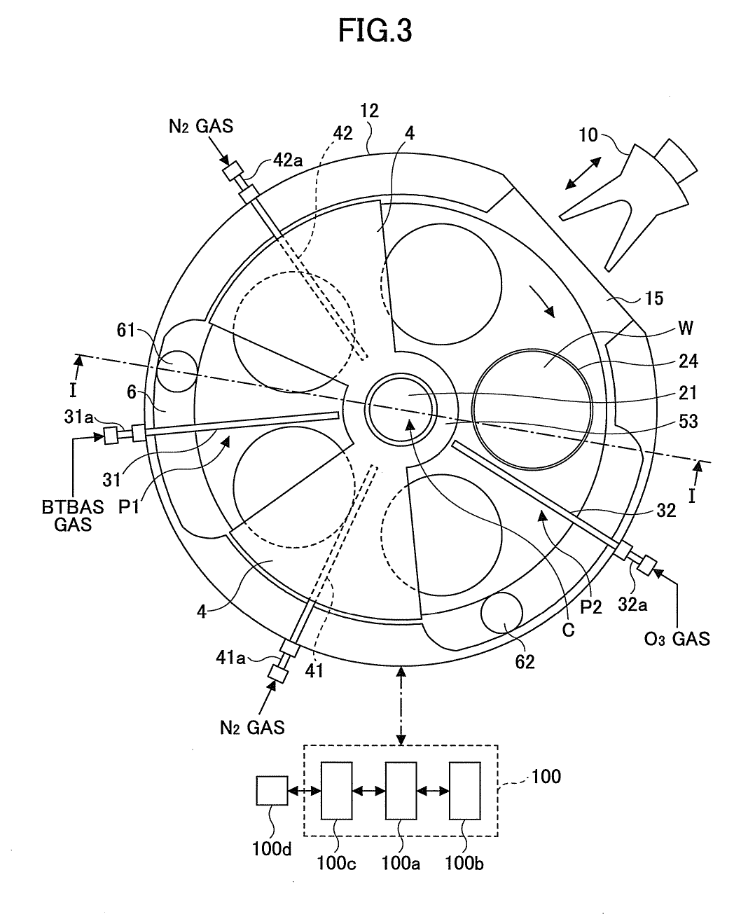

Referring to FIG. 1, which is a cut-away diagram taken along I-I line in FIG. 3, a film deposition apparatus according to an embodiment of the present invention has a vacuum chamber 1 having a flattened cylinder shape, and a turntable 2 that is located inside the chamber 1 and has a rotation center at a center of the vacuum chamber 1. The vacuum chamber 1 is made so that a ceiling plate 11 can be separated from a chamber body 12. The ceiling plate 11 is pressed onto the chamber body 12 via a ceiling member such as an O ring 13, so that the vacuum chamber 1 is hermetically sealed. On the other hand, the ceiling plate 11 can be raised by a driving mechanism (not shown) when the ceiling plate 11 has to be removed from the chamber body 12.

The turntable 2 is rotatably fixed onto a cylindrically shaped core portion 21. The core portion 21 is fixed on a top end of a rotational shaft 22 that extends in a vertical direction. The rotational shaft 22 penetrates a bottom portion 14 of the chamber body 12 and is fixed at the lower end to a driving mechanism 23 that can rotate the rotational shaft 22 clockwise, in this embodiment. The rotation shaft 22 and the driving mechanism 23 are housed in a case body 20 having a cylinder with a bottom. The case body 20 is hermetically fixed to a bottom surface of the bottom portion 14 via a flanged pipe portion 20a, which isolates an inner environment of the case body 20 from an outer environment.

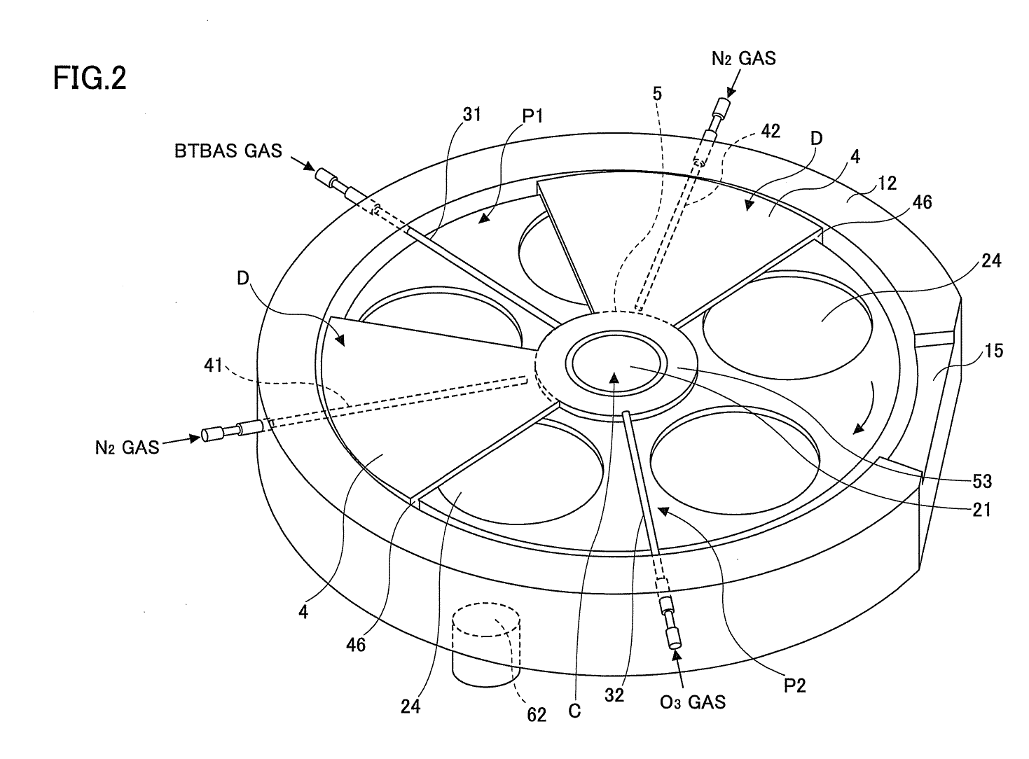

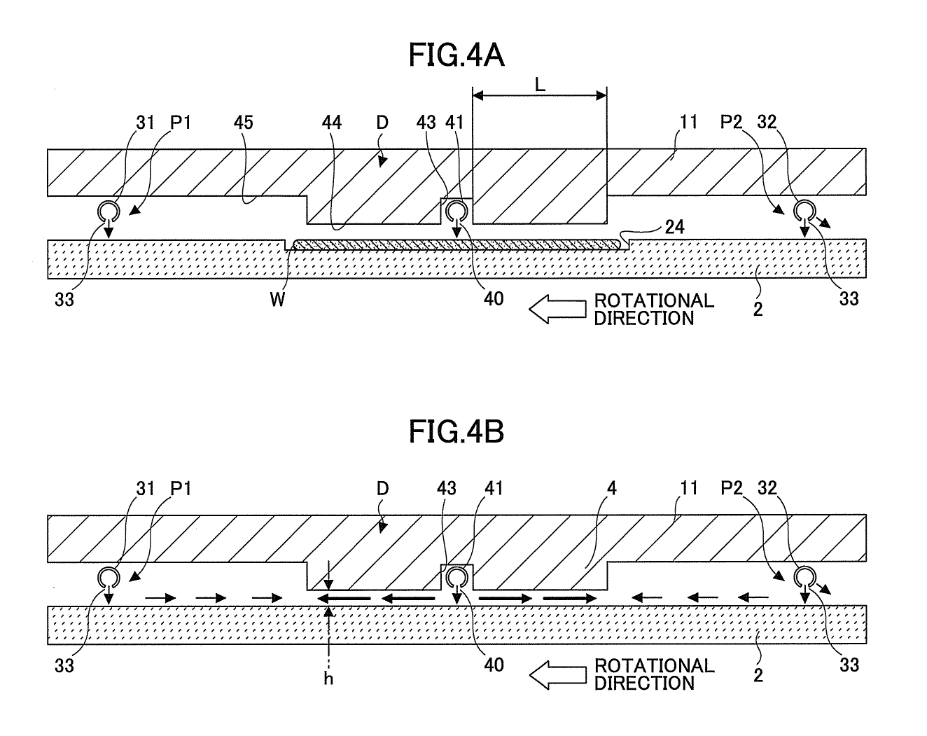

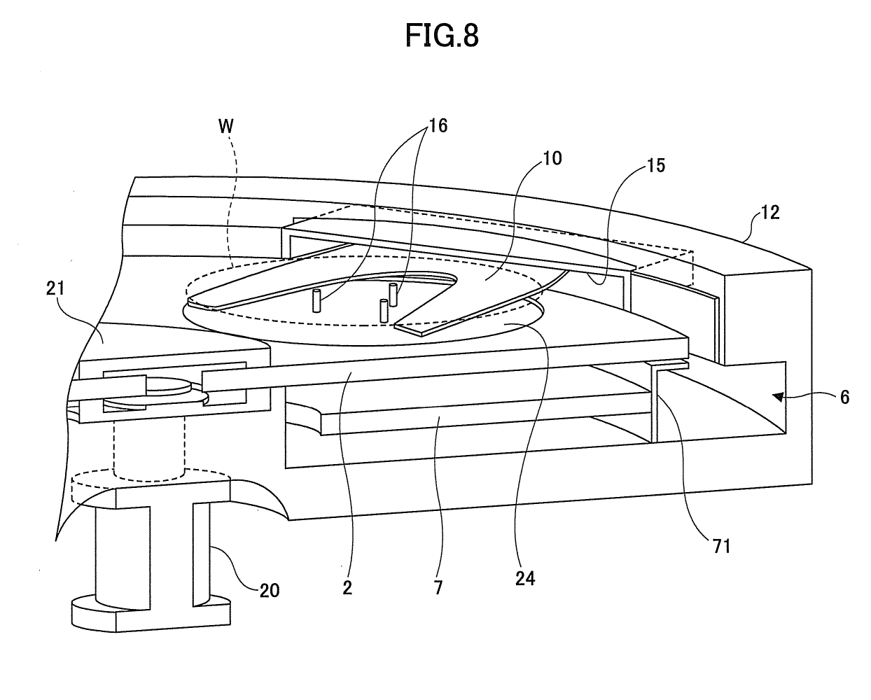

As illustrated in FIGS. 2 and 3, plural (five in the illustrated example) circular concave portions 24, each of which receives a wafer W, are formed in a top surface of the turntable 2, although only one wafer W is illustrated in FIG. 3. The concave portions 24 are located at equal angular intervals in the turntable 2. FIG. 4A is a projected cross-sectional diagram taken along an arc extending from a first reaction gas nozzle 31 to a second reaction gas nozzle 32 in FIG. 3. As shown in FIG. 4A, the concave portion 24 has a diameter slightly larger, for example, by 4 mm than the diameter of the wafer W and a depth equal to a thickness of the wafer W. Therefore, when the wafer W is placed in the concave portion 24, a surface of the wafer W is at the same elevation of a surface of an area of the turntable 2, the area excluding the concave portions 24. If there is a relatively large step between the area and the wafer W, gas flow turbulence is caused by the step, which may affect thickness uniformity across the wafer W. This is why the two surfaces are at the same elevation. While “the same elevation” may mean here that a height difference is less than or equal to about 5 mm, the difference has to be as close to zero as possible to the extent allowed by machining accuracy. In the bottom of the concave portion 24 there are formed three through holes (not shown) through which three corresponding elevation pins (see FIG. 8) are raised/lowered. The elevation pins support a back surface of the wafer W and raises/lowers the wafer W.

The concave portions 24 are wafer W receiving areas provided to position the wafers W and prevent the wafers W from being thrown out by centrifugal force caused by rotation of the turntable 2. However, the wafer W receiving areas are not limited to the concave portions 24, but may be performed by guide members that are located at predetermined angular intervals on the turntable 2 to hold the edges of the wafers W. For example, the wafer W receiving areas may be performed by electrostatic chucks. In this case, an area where the wafer W is placed corresponds to a substrate placement part Referring again to FIGS. 2 and 3, the chamber 1 includes a first reaction gas nozzle 31, a second reaction gas nozzle 32, and separation gas nozzles 41, 42 above the turntable 2, all of which extend in radial directions and at predetermined angular intervals. With this configuration, the concave portions 24 can move through and below the nozzles 31, 32, 41, and 42. In the illustrated example, the second reaction gas nozzle 32, the separation gas nozzle 41, the first reaction gas nozzle 31, and the separation gas nozzle 42 are arranged clockwise in this order. These gas nozzles 31, 32, 41, and 42 penetrate the circumferential wall portion of the chamber body 12 and are supported by attaching their base ends, which are gas inlet ports 31a, 32a, 41a, 42a, respectively, on the outer circumference of the wall portion. Although the gas nozzles 31, 32, 41, 42 are introduced into the chamber 1 from the circumferential wall portion of the chamber 1 in the illustrated example, these nozzles 31, 32, 41, 42 may be introduced from a ring-shaped protrusion portion 5 (described later). In this case, an L-shaped conduit may be provided in order to be open on the outer circumferential surface of the protrusion portion 5 and on the outer top surface of the ceiling plate 11. With such an L-shaped conduit, the nozzle 31 (32, 41, 42) can be connected to one opening of the L-shaped conduit inside the chamber 1 and the gas inlet port 31a (32a, 41a, 42a) can be connected to the other opening of the L-shaped conduit outside the vacuum chamber 1.

Although not illustrated in the figures, the reaction gas nozzle 31 is connected to a gas supplying source of bis(tertiary-butylamino)silane (BTBAS), which is a first source gas, and the reaction gas nozzle 32 is connected to a gas supplying source of O₃ (ozone) gas, which is a second source gas.

The reaction gas nozzles 31, 32 have plural ejection holes 33 to eject the corresponding source gases downward. The plural ejection holes 33 are arranged in longitudinal directions of the reaction gas nozzles 31, 32 at predetermined intervals. The ejection holes 33 have an inner diameter of about 0.5 mm, and are arranged at intervals of about 10 mm in this embodiment. The reaction gas nozzles 31, 32 are a first reaction gas supplying portion and a second reaction gas supplying portion, respectively, in this embodiment. In addition, an area below the reaction gas nozzle 31 is a first process area P1 in which the BTBAS gas is adsorbed on the wafer W, and an area below the reaction gas nozzle 32 is a second process area P2 in which the O₃ gas is adsorbed on the wafer W.

On the other hand, the separation gas nozzles 41, 42 are connected to gas supplying sources of N₂ (nitrogen) gas (not shown). The separation gas nozzles 41, 42 have plural ejection holes 40 to eject the separation gases downward from the plural ejection holes 40. The plural ejection holes 40 are arranged at predetermined intervals in longitudinal directions of the separation gas nozzles 41, 42. The ejection holes 40 have an inner diameter of about 0.5 mm, and are arranged at intervals of about 10 mm in this embodiment.

The separation gas nozzles 41, 42 are provided in separation areas D that are configured to separate the first process area P1 and the second process area P2. In each of the separation areas D, there is provided a convex portion 4 on the ceiling plate 11, as shown in FIGS. 2 through 4. The convex portion 4 has a top view shape of a sector whose apex lies at the center of the vacuum chamber 1 and whose arced periphery lies near and along the inner circumferential wall of the chamber body 12. In addition, the convex portion 4 has a groove portion 43 that extends in the radial direction as if the groove portion 43 substantially bisected the convex portion 4. The separation gas nozzle 41 (42) is located in the groove portion 43. A circumferential distance between the center axis of the separation gas nozzle 41 (42) and one side of the sector-shaped convex portion 4 is substantially equal to the other circumferential distance between the center axis of the separation gas nozzle 41 (42) and the other side of the sector-shaped convex portion 4. Incidentally, while the groove portion 43 is formed in order to bisect the convex portion 4 in this embodiment, the groove portion 42 is formed so that an upstream side of the convex portion 4 relative to the rotation direction of the turntable 2 is wider, in other embodiments.

With the above configuration, there are flat low ceiling surfaces 44 (first ceiling surfaces) on both sides of the separation gas nozzle 41 (42), and high ceiling surfaces 45 (second ceiling surfaces) outside of the corresponding low ceiling surfaces 44, as illustrated in FIG. 4A. The convex portion 4 (ceiling surface 44) provides a separation space, which is a thin or narrow space H, between the convex portion 4 and the turntable 2 in order to impede the first and the second gases from entering the thin space and from being mixed.

Referring to FIG. 4B, the O₃ gas is impeded from entering the space between the convex portion 4 and the turntable 2, the O₃ gas flowing toward the convex portion 4 from the reaction gas nozzle 32 along the rotation direction of the turntable 2, and the BTBAS gas is impeded from entering the space between the convex portion 4 and the turntable 2, the BTBAS gas flowing toward the convex portion 4 from the reaction gas nozzle 31 along the counter-rotation direction of the turntable 2. “The gases being impeded from entering” means that the N₂ gas as the separation gas ejected from the separation gas nozzle 41 diffuses between the first ceiling surfaces 44 and the upper surface of the turntable 2 and flows out to a space below the second ceiling surfaces 45, which are adjacent to the corresponding first ceiling surfaces 44 in the illustrated example, so that the gases cannot enter the separation space from the space below the second ceiling surfaces 45. “The gases cannot enter the separation space” means not only that the gas are completely prevented from entering the separation space, but that the gases cannot proceed farther toward the separation gas nozzle 41 and thus be mixed with each other even when a fraction of the reaction gases to enter the separation space. Namely, as long as such effect is demonstrated, the separation area D is to separate the first process area P1 and the second process area P2. Incidentally, the BTBAS gas or the O₃ gas adsorbed on the wafer W can pass through below the convex portion 4. Therefore, the gases in “the gases being impeded from entering” mean the gases in a gaseous phase.

Referring to FIGS. 1, 2, and 3, a ring-shaped protrusion portion 5 is provided on a back surface of the ceiling plate 11 so that the inner circumference of the protrusion portion 5 faces the outer circumference of the core portion 21. The protrusion portion 5 opposes the turntable 2 at an outer area of the core portion 21. In addition, a back surface of the protrusion portion 5 and a back surface of the convex portion 4 form one plane surface. In other words, a height of the back surface of the protrusion portion 5 from the turntable 2 is the same as a height of the back surface of the convex portion 4, which will be referred to as a height h below. Incidentally, the convex portion 4 is formed not integrally with but separately from the protrusion portion 5 in other embodiments. FIGS. 2 and 3 illustrate the inner configuration of the vacuum chamber 1 whose top plate 11 is removed while the convex portions 4 remain inside the vacuum chamber 1.

The separation area D is configured by forming the groove portion 43 in a sector-shaped plate to be the convex portion 4, and locating the separation gas nozzle 41 (42) in the groove portion 43 in the present embodiment. However, two sector-shaped plates may be attached on the lower surface of the ceiling plate 11 by screws so that the two sector-shaped plates are located on both sides of the separation gas nozzle 41 (42).

In the present embodiment, the separation gas nozzle 41 (42) includes discharge holes of an opening diameter of, for example, 0.5 mm directed downward, and are arranged along a longitudinal direction of the nozzle at intervals of 10 mm. Similarly, each of the reaction gas nozzles 31 and 32 includes discharge holes of an opening diameter of, for example, 0.5 mm directed downward, and are arranged along a longitudinal direction of the nozzle at intervals of 10 mm.

When the wafer W having a diameter of about 300 mm is supposed to be processed in the vacuum chamber 1, the convex portion 4 has a circumferential length of, for example, about 146 mm along an inner arc li (FIG. 3) that is at a distance 140 mm from the rotation center of the turntable 2, and a circumferential length of, for example, about 502 mm along an outer arc lo (FIG. 3) corresponding to the outermost portion of the concave portions 24 of the turntable 2 in this embodiment. In addition, a circumferential length from one side wall of the convex portion 4 through the nearest side wall of the groove portion 43 along the outer arc lo is about 246 mm.

In addition, the height h (FIG. 4A) of the back surface of the convex portion 4, or the ceiling surface 44, measured from the top surface of the turntable 2 (or the wafer W) is, for example, about 0.5 mm through about 10 mm, and preferably about 4 mm. In this case, the rotational speed of the turntable 2 is, for example, 1 through 500 revolutions per minute (rpm). In order to ascertain the separation function performed by the separation area D, the size of the convex portion 4 and the height h of the ceiling surface 44 from the turntable 2 may be determined depending on the pressure in the chamber 1 and the rotational speed of the turntable 2 through experimentation. Incidentally, the separation gas is N₂ in this embodiment but may be an inert gas such as He and Ar, or H₂ in other embodiments, as long as the separation gas does not affect the deposition of silicon dioxide.

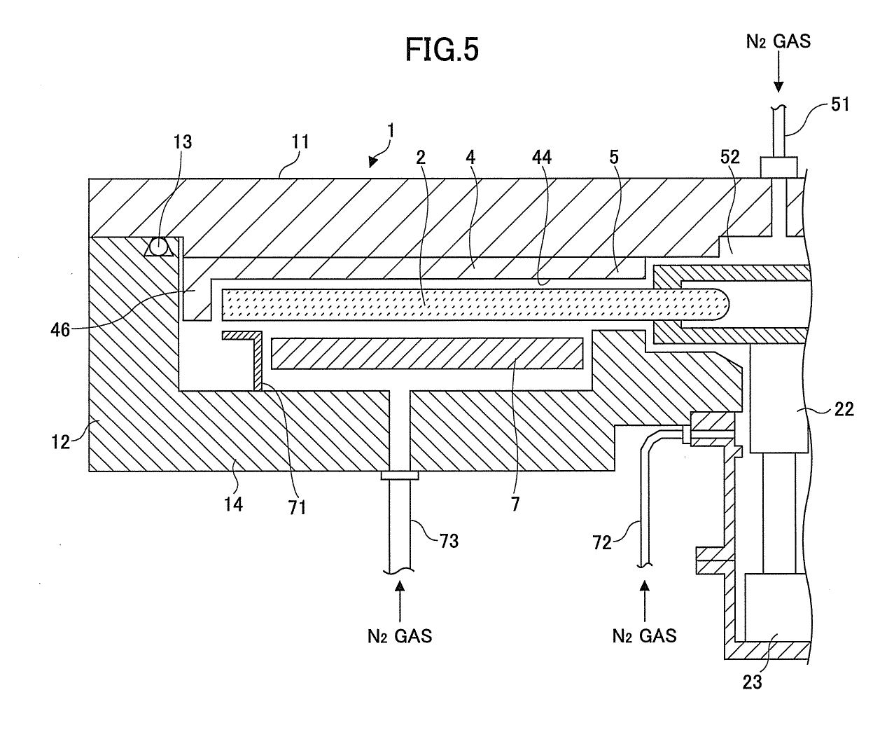

FIG. 5 illustrates a half portion of a cross-sectional view of the chamber 1, taken along a I-I line in FIG. 3, where the convex portion 4 is shown along with the protrusion portion 5 formed integrally with the convex portion 4. Referring to FIG. 5, the convex portion 4 has a bent portion 46 that bends in an L-shape at the outer circumferential edge of the convex portion 4. Although there are slight gaps between the bent portion 46 and the turntable 2 and between the bent portion 46 and the chamber body 12 because the convex portion 4 is attached on the back surface of the ceiling portion 11 and removed from the chamber body 12 along with the ceiling portion 11, the bent portion 46 substantially fills out a space between the turntable 2 and the chamber body 12, thereby preventing the first reaction gas (BTBAS) ejected from the first reaction gas nozzle 31 and the second reaction gas (ozone) ejected from the second reaction gas nozzle 32 from being mixed through the space between the turntable 2 and the chamber body 12. The gaps between the bent portion 46 and the turntable 2 and between the bent portion 46 and the chamber body 12 may be the same as the height h of the ceiling surface 44 from the turntable 2. In the illustrated example, a side wall facing the outer circumferential surface of the turntable 2 serves as an inner circumferential wall of the separation area D.

Now, referring again to FIG. 1, which is a cross-sectional view taken along a I-I line in FIG. 3, the chamber body 12 has an indented portion at the inner circumferential portion opposed to the outer circumferential surface of the turntable 2. The dented portion is referred to as an evacuation area 6 hereinafter. Below the evacuation area 6, there is an evacuation port 61 (see FIG. 3 for another evacuation port 62) which is connected to a vacuum pump 64 via an evacuation pipe 63, which can also be used for the evacuation port 62. In addition, the evacuation pipe 63 is provided with a pressure controller 65. Plural pressure controllers 65 may be provided to the corresponding evacuation ports 61, 62.

Referring again to FIG. 3, the evacuation port 61 is located between the first reaction gas nozzle 31 and the convex portion 4 that is located downstream relative to the clockwise rotation direction of the turntable 2 in relation to the first reaction gas nozzle 31, when viewed from above. With this configuration, the evacuation port 61 can substantially exclusively evacuate the BTBAS gas ejected from the reaction gas nozzle 31. On the other hand, the evacuation port 62 is located between the first reaction gas nozzle 32 and the convex portion 4 that is located downstream relative to the clockwise rotation direction of the turntable 2 in relation to the first reaction gas nozzle 32, when viewed from above. With this configuration, the evacuation port 62 can substantially exclusively evacuate the O₃ gas ejected from the reaction gas nozzle 32. Therefore, the evacuation ports 61, 62 so configured may assist the separation areas D to prevent the BTBAS gas and the O₃ gas from being mixed.

Although the two evacuation ports 61, 62 are made in the chamber body 12 in this embodiment, three evacuation ports may be provided in other embodiments. For example, an additional evacuation port may be made in an area between the second reaction gas nozzle 32 and the separation area D located upstream relative to the clockwise rotation of the turntable 2 in relation to the second reaction gas nozzle 32. In addition, a further additional evacuation port may be made somewhere in the chamber body 12. While the evacuation ports 61, 62 are located below the turntable 2 to evacuate the chamber 1 through an area between the inner circumferential wall of the chamber body 12 and the outer circumferential surface of the turntable 2 in the illustrated example, the evacuation ports may be located in the side wall of the chamber body 12. In addition, when the evacuation ports 61, 62 are provided in the side wall of the chamber body 12, the evacuation ports 61, 62 may be located higher than the turntable 2. In this case, the gases flow along the upper surface of the turntable 2 into the evacuation ports 61, 62 located higher the turntable 2. Therefore, it is advantageous in that particles in the chamber 1 are not blown upward by the gases, compared to when the evacuation ports are provided, for example, in the ceiling plate 11.

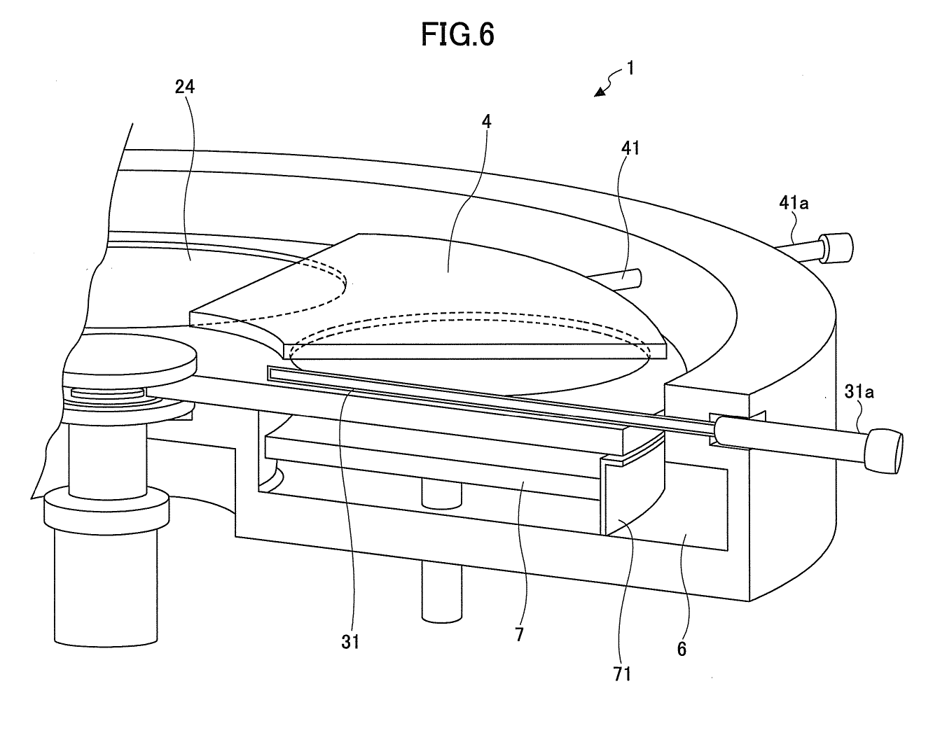

As illustrated in FIGS. 1, 2, and 6, a ring-shaped heater unit 7 as a heating portion is provided in a space between the bottom portion 14 of the chamber body 12 and the turntable 2, so that the wafers W placed on the turntable 2 are heated through the turntable 2 at a temperature determined by a process recipe. In addition, a cover member 71 is provided beneath the turntable 2 and near the outer circumference of the turntable 2 in order to surround the heater unit 7, so that the space where the heater unit 7 is located is partitioned from the outside area of the cover member 71. The cover member 71 has a flange portion 71a at the top. The flange portion 71a is arranged so that a slight gap is maintained between the back surface of the turntable 2 and the flange portion in order to prevent gas from flowing inside the cover member 71.

Referring back to FIG. 1, the bottom portion 14 has a raised portion in an inside area of the ring-shaped heater unit 7. The top surface of the raised portion comes close to the back surface of the turntable 2 and the core portion 21, leaving slight gaps between the raised portion and the turntable 2 and between the raised portion and the core portion 21. In addition, the bottom portion 14 has a center hole through which the rotation shaft 22 passes. The inner diameter of the center hole is slightly larger than the diameter of the rotation shaft 22, leaving a gap for communication with the case body 20 through the flanged pipe portion 20a. A purge gas supplying pipe 72 is connected to an upper portion of the flanged pipe portion 20a. In addition, plural purge gas supplying pipes 73 are connected at predetermined angular intervals to areas below the heater unit 7 in order to purge the space where the heater unit 7 is housed.

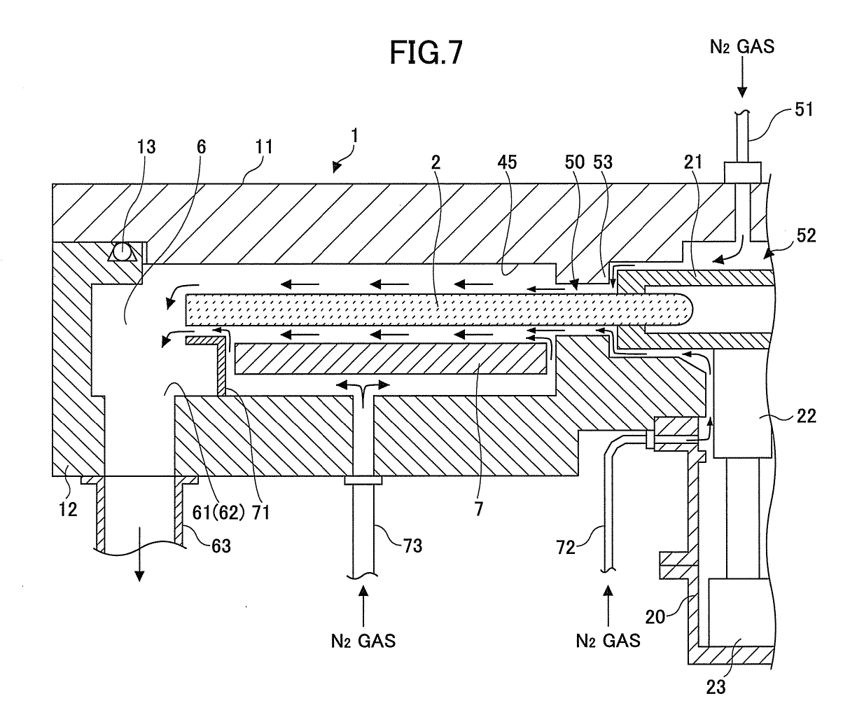

With these configurations, N₂ purge gas may flow from the purge gas supplying pipe 72 to the heater unit space through the gap between the rotation shaft 22 and the center hole of the bottom portion 14, the gap between the core portion 21 and the raised portion of the bottom portion 14, and the gap between the raised portion of the bottom portion 14 and the back surface of the turntable 2. In addition, N₂ purge gas may flow from the purge gas supplying pipes 73 to the space below the heater unit 7. Then, this N₂ purge gas flows into the evacuation port 61 through the gap between the flange portion 71a of the cover member 71 and the back surface of the turntable 2. This flow of the N₂ purge gas is schematically illustrated by arrows in FIG. 7. This N₂ purge gas serves as a separation gas that prevents the first (second) reaction gas from flowing around the space below the turntable 2 to be mixed with the second (first) reaction gas.

Referring to FIG. 7, a separation gas supplying pipe 51 is connected to the top center portion of the ceiling plate 11 of the chamber 1, so that N₂ gas is supplied as a separation gas to a space 52 between the ceiling plate 11 and the core portion 21. The separation gas supplied to the space 52 flows through the thin gap 50 between the protrusion portion 5 and the turntable 2 and then along the top surface of the turntable 2, and reaches the evacuation area 6. Because the space 52 and the gap 50 are filled with the N2 gas, the reaction gases (BTBAS, O₃) cannot be mixed through the center portion of the turntable 2. In other words, the film deposition apparatus according to this embodiment is provided with a center area C that is defined by the center portion of the turntable 2 and the chamber 1 in order to isolate the first process area P1 and the second process area P2 and is configured to have an ejection opening that ejects the separation gas toward the top surface of the turntable 2. The ejection opening corresponds to the gap 50 between the protrusion portion 5 and the turntable 2, in the illustrated example.

In addition, a transfer opening 15 is formed in a side wall of the chamber body 12 as shown in FIGS. 2, 3 and 8. Through the transfer opening 15, the wafer W is transferred into or out from the chamber 1 by a transfer arm 10 (FIGS. 3 and 8). The transfer opening 15 is provided with a gate valve (not shown) by which the transfer opening 15 is opened or closed. When the concave portion 24 of the turntable 2 is in alignment with the transfer opening 15 and the gate valve is opened, the wafer W is transferred into the chamber 1 and placed in the concave portion 24 as a wafer receiving portion of the turntable 2 from the transfer arm 10. In order to lower/raise the wafer W into/from the concave portion 24, there are provided elevation pins 16 that are raised or lowered through corresponding through holes formed in the concave portion 24 of the turntable 2 by an elevation mechanism (not illustrated in the figure).

In addition, the film deposition apparatus according to this embodiment is provided with a control portion 100 that controls total operations of the deposition apparatus. The control portion 100 includes a process controller 100a formed of, for example, a computer, a user interface portion 100b, and a memory device 100c. The user interface portion 100b has a display that shows operations of the film deposition apparatus, and an input/output (I/O) device including a key board and a touch panel that allows an operator of the film deposition apparatus to select a process recipe and an administrator of the film deposition apparatus to change parameters in the process recipe.

The memory device 100c stores a control program and a process recipe that cause the controlling portion 100 to carry out various operations of the deposition apparatus, and various parameters in the process recipe. These programs have groups of steps for carrying out the operations described later, for example. These programs are installed into and run by the process controller 100a by instructions from the user interface portion 100b. In addition, the programs are stored in a computer readable storage medium 100d and installed into the memory device 100c from the storage medium 100d. The computer readable storage medium 100d may be a hard disk, a compact disc, a magneto optical disk, a memory card, a floppy disk, or the like. Moreover, the programs may be downloaded to the memory device 100c through a communications network.

Next, operations of the film deposition apparatus according to this embodiment of the present invention are described. First, the turntable 2 is rotated so that the concave portion 24 is in alignment with the transfer opening 15, and the gate valve (not shown) is open. Second, the wafer W is brought into the chamber I through the transfer opening 15 by the transfer arm 10. The wafer W is received by the elevation pins 16 and lowered to the concave portion 24 by the elevation pins 16 driven by the elevation mechanism (not illustrated in the figure) after the transfer arm 10 is pulled away from the chamber 1. Then, the series of operations above are repeated five times, and thus five wafers W are loaded on the turntable 2. Next, the vacuum pump 64 (FIG. 1) is activated in order to maintain the chamber 1 at a predetermined reduced pressure. The turntable 2 starts rotating clockwise when seen from above. The turntable 2 is heated to a predetermined temperature (e.g., 300° C.) in advance by the heater unit 7, which in turn heats the wafers W on the turntable 2. After the wafers W are heated and maintained at the predetermined temperature, which may be confirmed by a temperature sensor (not shown), the first reaction gas (BTBAS) is supplied to the first process area P1 through the first reaction gas nozzle 31, and the second reaction gas (O₃) is supplied to the second process area P2 through the second reaction gas nozzle 32. In addition, the separation gases (N₂) are supplied to the separation areas D through the separation nozzles 41, 42.

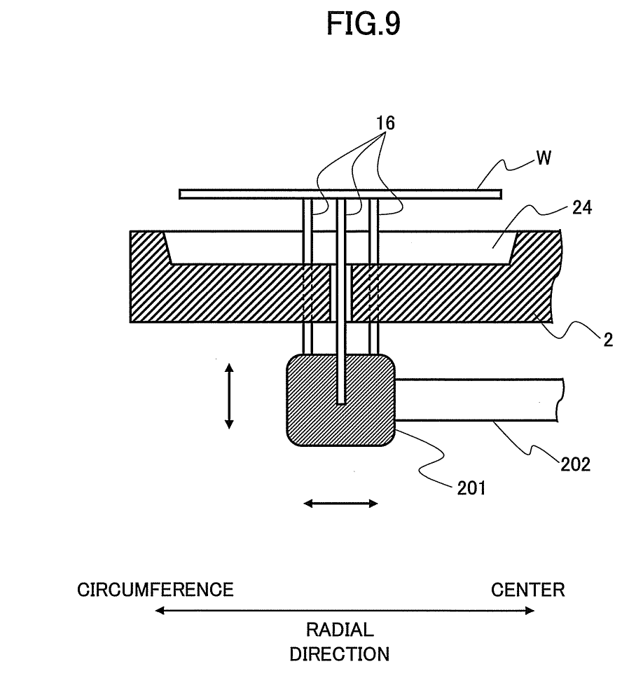

Here, a description will be given, with reference to FIG. 9, of a transfer of the wafer W in the present embodiment.

As illustrated in FIG. 9, in the present embodiment, an elevation pin moving part 201 is provided to move the elevation pins 16, which are for transferring the wafer W, in an upward and downward direction and a radial direction in the concave portions 24 of the turntable 2. The elevation pin moving part 201 is connected to a moving mechanism via a control shaft 202, and a movement of the elevation pins 16 is controlled based on a control signal from the control part 100 illustrated in FIG. 3. The elevation pin moving part 201 can move three elevation pins 16 upward and downward, and also move the three elevation pins 16 simultaneously in a radial direction. Only the three elevation pins 16 may be moved in the upward and downward directions and the radial direction, or the elevation pins 16 and the elevation pin moving part 201 together may be moved in the upward and downward directions and the radial direction.

Alternatively, only the elevation pins 16 may be moved in the upward and downward directions while the elevation pins 16 and the elevation pin moving part 201 together may be moved in the radial direction. Alternatively, the elevation pins 16 and the elevation pin moving part 201 together may be moved in the upward and downward directions while only the elevation pins 16 may be moved in the radial direction.

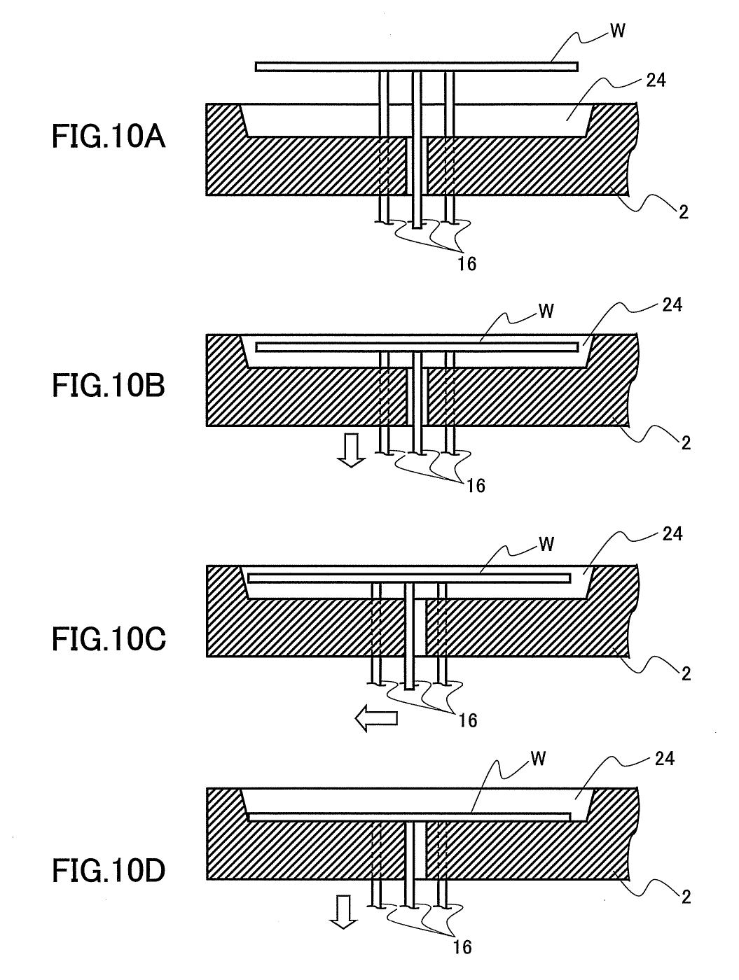

A description will be given, with reference to FIGS. 10A through 10D, of a procedure of transferring the wafer W in the present embodiment. It is assumed that, in the present embodiment, a diameter of the wafer is 300 mm and a diameter of each concave portion 24 is 304 mm. Accordingly, the concave portion 24 is larger than the wafer W by 4 mm.

FIG. 10A illustrates a state where the wafer W is placed on the three elevation pins 16 provided to the concave portion 24 of the turntable 2 by the conveyance arm 10, that is, a state after completion of a substrate placing process. The conveyance arm 10 is not illustrated in the figure because the conveyance arm 10 moves to a side of the conveyance port 15 after placing the wafer W on the three elevation pins 16.

Thereafter, as illustrated in FIG. 10B, the three elevation pins 16 are entirely moved downward to move the wafer W close to the concave portion 24. Then, after the wafer W is moved downward until the wafer W enters the concave portion 24, the movement of the elevation pins is stopped (first downward moving process). In this state, the wafer W is at a position lower than the surface of the table 2.

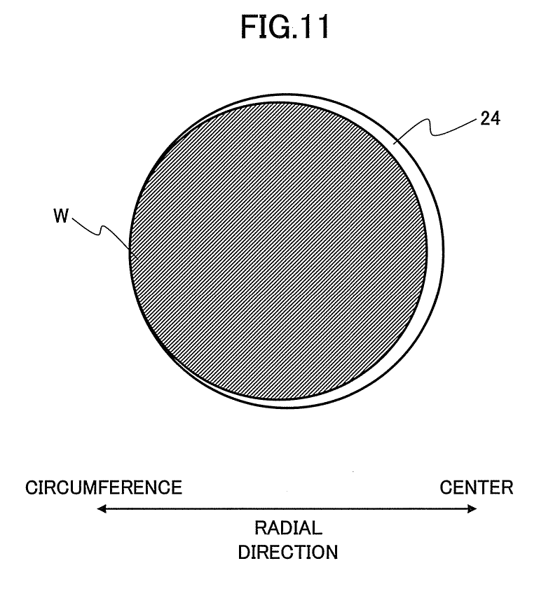

Thereafter, as illustrated in FIG. 10C, the wafer W is horizontally moved to a position where the circumference of the wafer W contacts or moves to a position close to a wall surface of the concave portion 24 of the turntable 2 (horizontally moving process). A portion of the concave portion 24 in contact with or close to the circumference of the wafer W is a portion of the wall surface of the concave portion 24, which is most distant from the center of the turntable 2. The movement of the wafer W is achieved by entirely moving the three elevation pins 16 in a radially outward direction of the turntable 2. The movement of the elevation pins 16 at this time is achieved only by the movement in the radial direction of the turntable 2. There may be a case in which the wall surface of the concave portion 24 of the turntable 2 is tapered. In such a case, it is desirable to move the wafer W to a predetermined position close to the wall surface rather than bringing the wafer W into contact with the wall surface of the concave portion 24. Thereafter, as illustrated in FIG. 10D, the three elevation pins 16 are moved downward to bring the wafer W into contact with the bottom part of the concave portion 24 of the turntable 2 to place the wafer W on the bottom of the concave portion 24 (second downward movement process). According to the above-mentioned operation, the wafer W is placed on the bottom part of the concave portion 24 of the turntable 2 as illustrated in FIG. 11.

The wafer W is in contact with or close to the wall surface of the concave portion 24 of the turntable 2 in the circumference thereof in a radial direction of the turntable 2. Thus, even if the turntable 2 rotates at a high speed, the wafer W does not forcefully hit the wall surface of the concave portion 24 of the turntable 2 due to a centrifugal force. Accordingly, there is little possibility of generation of cracking or chipping of the wafer W. Thus, generation of particles due to a contact of the wafer W with the wall surface of the concave portion 24 of the turntable 2 is prevented, and an environmental pollution inside the apparatus and incorporation of foreign matters into a deposited film can be prevented.

Such a transfer of the wafer W is performed by rotating the turntable 2 intermittently so that five pieces of wafer W are placed in the five concave portions 24 of the turntable 2, respectively. Subsequently, the vacuum chamber 1 is evacuated by the vacuum pump 64 at a previously set pressure, and the wafer W is heated by the heater unit 7 while rotating the turntable 2 clockwise. Specifically, the turntable 2 is heated previously, for example, at 300° C. by the heater unit 7, and the wafer W is heated by being placed on the heated turntable 2. After checking that the temperature of the wafer W reaches a setting temperature by a temperature sensor, which is not illustrated in the figure, the BTBAS gas and the O₃ gas are discharged from the first reaction gas nozzle 31 and the second reaction gas nozzle 32, and the Ne [N₂?]gas, which is a separation gas, is discharged from the separation gas nozzles 41 and 42.

When the wafer W passes through the first process area P1 under the first reaction gas nozzle 31, molecules of BTBAS are adsorbed onto the surface of the wafer W, and when the wafer W passes through the second process area P2 under the second reaction gas nozzle 32, molecules of O₃ are adsorbed onto the surface of the wafer W, thereby oxidizing the BTBAS molecules by the O₃ molecules. Accordingly, if the wafer W passes through the area P1 and the area P2 one time by the rotation of the turntable 2, a single molecular layer of silicon oxide is formed on the surface of the wafer W. Then, the wafer W passes through the areas P1 and the areas P2 alternatively a plurality of times, which results in deposition of a silicon oxide film having a predetermined film thickness on the surface of the wafer W. After the silicon oxide film having a predetermined film thickness is deposited, the supply of the BTBAS gas and the O₃ gas is stopped and the rotation of the turntable is also stopped. Then, the wafer W is sequentially carried out of the vacuum chamber 1 by the conveyance arm 10 according to a reverse operation of the carry-in operation.

The wafer W alternately passes through the first process area P1, in which the first reaction gas nozzle 31 is provided, and the second process area P2, in which the second reaction gas nozzle 32 is provided. Thereby, the BTBAS gas is adsorbed onto the wafer W, and, then, the O₃ gas is adsorbed onto the wafer W, which results in oxidation of the BTBAS molecules and formation of one or a plurality of silicon oxide molecular layers. Thus, the silicon oxide molecular layers are laminated sequentially, thereby forming a silicon oxide film having a predetermined film thickness.

In addition, during the deposition operations above, the N₂ gas as the separation gas is supplied from the separation gas supplying pipe 51, and is ejected toward the top surface of the turntable 2 from the center area C, that is, the gap 50 between the protrusion portion 5 and the turntable 2. In this embodiment, a space below the second ceiling surface 45, where the reaction gas nozzle 31 (32) is arranged, has a lower pressure than the center area C and the thin space between the first ceiling surface 44 and turntable 2. This is because the evacuation area 6 is provided adjacent to the space below the ceiling surface 45 and the space is directly evacuated through the evacuation area 6. Additionally, it is partly because the thin space is provided so that the height h can maintain the pressure difference between the thin space and the place where the reaction gas nozzle 31 (32) or the first (the second) process area P1 (P2) is located.

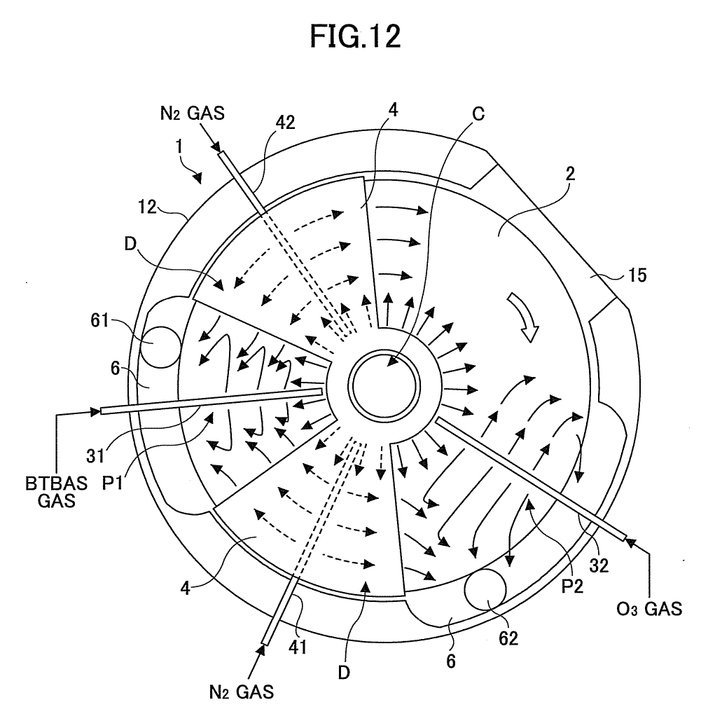

Next, the flow patterns of the gases supplied into the chamber 1 from the gas nozzles 31, 32, 41, 42 are described in reference to FIG. 12, which schematically shows the flow patterns. As shown, part of the O₃ gas ejected from the second reaction gas nozzle 32 hits and flows along the top surface of the turntable 2 (and the surface of the wafer W) in a direction opposite to the rotation direction of the turntable 2. Then, the O₃ gas is pushed back by the N₂ gas flowing along the rotation direction, and changes the flow direction toward the edge of the turntable 2 and the inner circumferential wall of the chamber body 12. Finally, this part of the O₃ gas flows into the evacuation area 6 and is evacuated from the chamber 1 through the evacuation port 62.

Another part of the O₃ gas ejected from the second reaction gas nozzle 32 hits and flows along the top surface of the turntable 2 (and the surface of the wafers W) in the same direction as the rotation direction of the turntable 2. This part of the O₃ gas mainly flows toward the evacuation area 6 due to the N₂ gas flowing from the center portion C and suction force through the evacuation port 62. On the other hand, a small portion of this part of the O₃ gas flows toward the separation area D located downstream of the rotation direction of the turntable 2 in relation to the second reaction gas nozzle 32 and may enter the gap between the ceiling surface 44 and the turntable 2. However, because the height h of the gap is designed so that the O₃ gas is impeded from flowing into the gap at film deposition conditions intended, the small portion of the O₃ gas cannot flow into the gap. Even when a small fraction of the O₃ gas flows into the gap, the fraction of the O₃ gas cannot flow farther into the separation area D, because the fraction of the O₃ gas can be pushed backward by the N₂ gas ejected from the separation gas nozzle 41. Therefore, substantially all the part of the O₃ gas flowing along the top surface of the turntable 2 in the rotation direction flows into the evacuation area 6 and is evacuated by the evacuation port 62, as shown in FIG. 12.

Similarly, part of the BTBAS gas ejected from the first reaction gas nozzle 31 to flow along the top surface of the turntable 2 (and the surface of the wafers W) in a direction opposite to the rotation direction of the turntable 2 is prevented from flowing into the gap between the turntable 2 and the ceiling surface 44 of the convex portion 4 located upstream relative to the rotation direction of the turntable 2 in relation to the first reaction gas supplying nozzle 31. Even if only a fraction of the BTBAS gas flows into the gap, the BTBAS gas is pushed backward by the N₂ gas ejected from the separation gas nozzle 41 in the separation area D. The BTBAS gas pushed backward flows toward the outer circumferential edge of the turntable 2 and the inner circumferential wall of the chamber body 12, along with the N₂ gases from the separation gas nozzle 41 and the center portion C, and then is evacuated by the evacuation port 61 through the evacuation area 6.

Another part of the BTBAS gas ejected from the first reaction gas nozzle 31 to flow along the top surface of the turntable 2 (and the surface of the wafers W) in the same direction as the rotation direction of the turntable 2, cannot flow into the gap between the turntable 2 and the ceiling surface 44 of the convex portion 4 located downstream relative to the rotation direction of the turntable 2 in relation to the first reaction gas supplying nozzle 31. Even if a fraction of this part of the BTBAS gas flows into the gap, this BTBAS gas is pushed backward by the N₂ gases ejected from the center portion C and the separation gas nozzle 42 in the separation area D. The BTBAS gas pushed backward flows toward the evacuation area 6, along with the N2 gases from the separation gas nozzle 41 and the center portion C, and then is evacuated by the evacuation port 61.

As stated above, the separation areas D may prevent the BTBAS gas and the O₃ gas from flowing thereinto, or may greatly reduce the amount of the BTBAS gas and the O₃ gas flowing thereinto, or may push the BTBAS gas and the O₃ gas backward. The BTBAS molecules and the O₃ molecules adsorbed on the wafer W are allowed to go through the separation area D, contributing to the film deposition.

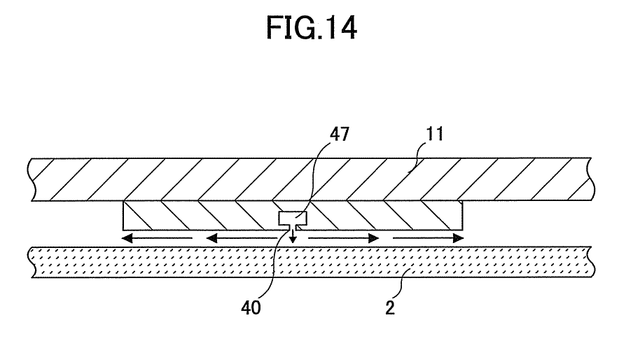

Additionally, the BTBAS gas in the first process area P1 (the O₃ gas in the second process area P2) is prevented from flowing into the center area C, because the separation gas is ejected toward the outer circumferential edge of the turntable 2 from the center area C, as shown in FIGS. 12 and 14. Even if a fraction of the BTBAS gas in the first process area P1 (the O₃ gas in the second process area P2) flows into the center area C, the BTBAS gas (the O₃ gas) is pushed backward, so that the BTBAS gas in the first process area P1 (the O₃ gas in the second process area P2) is prevented from flowing into the second process area P2 (the first process area P1) through the center area C.

Moreover, the BTBAS gas of the first process area P1 (the O₃ gas of the second process area P3) is prevented from flowing into the second process area P2 (the first process area P1) through the space between the turntable 2 and the inner wall of the chamber body 12. This is because the bent part 46 is formed downward from the convex portion 4, and a gap between the bent part 46 and the turntable 2 and the gap between the bent part 46 and the inner wall of the chamber body 12 substantially eliminate pressure communication between the two process areas because the gaps are as small as the height h of the ceiling surface 44 of the convex portion 4 from the turntable 2. Accordingly, the BTBAS gas is evacuated from the evacuation port 61, and the O₃ gas is evacuated from the evacuation port 62, and thus the two reaction gases are not mixed. In addition, the space below the turntable 2 is purged by the N₂ gas supplied from the purge gas supplying pipes 72, 73. Therefore, the BTBAS gas cannot flow through below the turntable 2 into the second process area P2.

After the film deposition process is completed, each wafer W is carried out of the vacuum chamber 1 by the conveyance arm 10 according to a reverse operation of the carry-in operation.

An example of process parameters preferable in the film deposition apparatus according to this embodiment is listed below.
rotational speed of the turntable 2: 1-500 rpm (in the case of the wafer W having a diameter of 300 mm)
pressure in the chamber 1: 1067 Pa (8 Torr)
wafer temperature: 350° C.
flow rate of BTBAS gas: 100 sccm
flow rate of O₃ gas: 10000 sccm
flow rate of N₂ gas from the separation gas nozzles 41, 42: 20000 sccm
flow rate of N₂ gas from the separation gas supplying pipe 51: 5000 sccm
the number of rotations of the turntable 2: 600 rotations (depending on the film thickness required)

According to the film deposition apparatus of this embodiment, because the film deposition apparatus has the separation areas D including the low ceiling surface 44 between the first process area P1, to which the BTBAS gas is supplied from the first reaction gas nozzle 31, and the second process area P2, to which the O₃ gas is supplied from the second reaction gas nozzle 32, the BTBAS gas (the O₃ gas) is prevented from flowing into the second process area P2 (the first process area P1) and being mixed with the O₃ gas (the BTBAS gas). Therefore, an MLD (or ALD) mode deposition of silicon dioxide is assuredly performed by rotating the turntable 2 on which the wafers W are placed in order to allow the wafers W to pass through the first process area P1, the separation area D, the second process area P2, and the separation area D. In addition, the separation areas D further include the separation gas nozzles 41, 42 from which the N2 gases are ejected in order to further assuredly prevent the BTBAS gas (the O₃ gas) from flowing into the second process area P2 (the first process area P1) and being mixed with the O₃ gas (the BTBAS gas). Moreover, because the chamber 1 of the film deposition apparatus according to this embodiment has the center area C having the ejection holes from which the N₂ gas is ejected, the BTBAS gas (the O₃ gas) is prevented from flowing into the second process area P2 (the first process area P1) through the center area C and being mixed with the O₃ gas (the BTBAS gas). Furthermore, because the BTBAS gas and the O₃ gas are not mixed, almost no deposits of silicon dioxide are made on the turntable 2, thereby reducing particle problems.

Incidentally, although the turntable 2 has the five concave portions 24 and five wafers W placed in the corresponding concave portions 24 can be processed in one run in this embodiment, only one wafer W is placed in one of the five concave portions 24, or the turntable 2 may have only one concave portion 24.

The reaction gases that may be used in the film deposition apparatus according to an embodiment of the present invention are dichlorosilane (DOCS), hexachlorodisilane (HCD), Trimethyl Aluminum (TMA), tetrakis-ethyl-methyl-amino-zirconium (TEMAZr), tris(dimethyl amino)silane (3DMAS), tetrakis-ethyl-methyl-amino-hafnium (TEMHf), bis(tetra methyl heptandionate)strontium (Sr(THD)₂) , (methyl-pentadionate)(bis-tetra-methyl-heptandionate)titanium (Ti(MPD)(THD)), monoamino-silane, or the like.

Because a larger centrifugal force is applied to the gases in the chamber 1 at a position closer to the outer circumference of the turntable 2, the BTBAS gas, for example, flows toward the separation area D at a higher speed in the position closer to the outer circumference of the turntable 2. Therefore, the BTBAS gas is more likely to enter the gap between the ceiling surface 44 and the turntable 2 in the position closer to the circumference of the turntable 2. Because of this situation, when the convex portion 4 has a greater width (a longer arc) toward the circumference, the BTBAS gas cannot flow farther into the gap in order to be mixed with the O₃ gas. In view of this, it is preferable for the convex portion 4 to have a sector-shaped top view, as explained in the above embodiment.

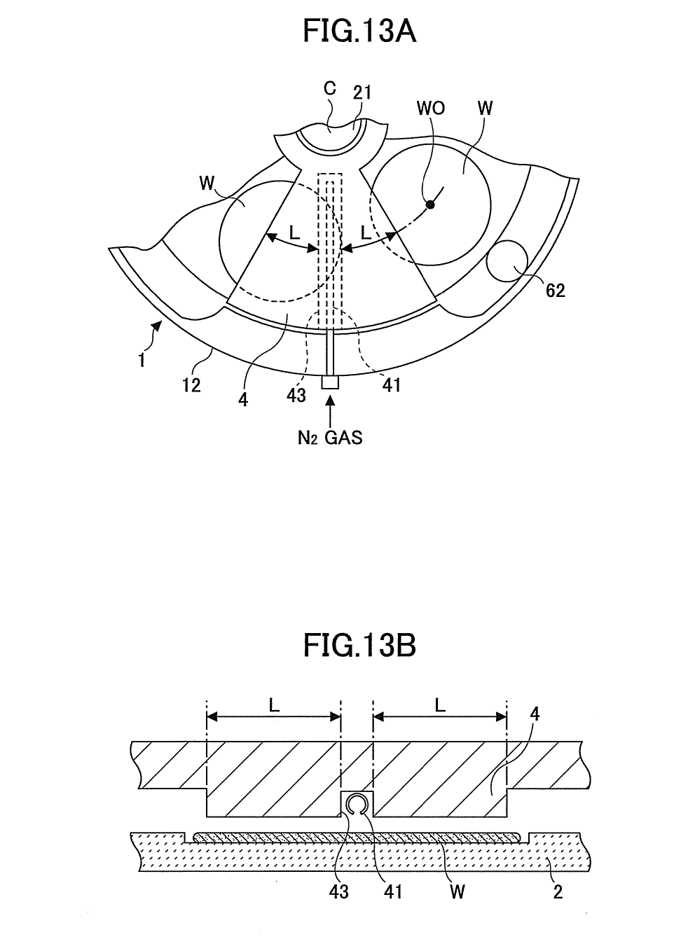

The size of the convex portion 4 (or the ceiling surface 44) is exemplified again below. Referring to FIGS. 13A and 13B, the ceiling surface 44 that creates the thin space in both sides of the separation gas nozzle 41 (42) may preferably have a length L ranging from about one-tenth of a diameter of the wafer W through about a diameter of the wafer W, preferably, about one-sixth or more of the diameter of the wafer W along an arc that corresponds to a route through which a wafer center WO passes. Specifically, the length L is preferably about 50 mm or more when the wafer W has a diameter of 300 mm. When the length L is small, the height h of the thin space between the ceiling surface 44 and the turntable 2 (wafer W) has to be accordingly small in order to effectively prevent the reaction gases from flowing into the thin space. However, when the length L becomes too small and thus the height h has to be extremely small, the turntable 2 may hit the ceiling surface 44, which may cause wafer breakage and wafer contamination through particle generation. Therefore, measures to damp vibration of the turntable 2 or measures to stably rotate the turntable 2 are required in order to prevent the turntable 2 hitting the ceiling surface 44. On the other hand, when the height h of the thin space is kept relatively greater while the length L is small, a rotation speed of the turntable 2 has to be lower in order to avoid the reaction gases flowing into the thin gap between the ceiling surface 44 and the turntable 2, which is rather disadvantageous in terms of production throughput. From these considerations, the length L of the ceiling surface 44 along the arc corresponding to the route of the wafer center WO is preferably about 50 mm or more when the wafers W having a diameter of 300 mm are processed, as stated above. However, the size of the convex portion 4 or the ceiling surface 44 is not limited to the above size, but may be adjusted depending on the process parameters and the size of the wafer to be used. In addition, as clearly understood from the above explanation, the height h of the thin space may be adjusted depending on an area of the ceiling surface 44 in addition to the process parameters and the size of the wafer to be used, as long as the thin space has a height that allows the separation gas to flow from the separation area D through the process area P1 (P2).

The separation gas nozzle 41 (42) is located in the groove portion 43 formed in the convex portion 4 and the lower ceiling surfaces 44 are located in both sides of the separation gas nozzle 41 (42) in the above embodiment. However, as shown in FIG. 14, a conduit 47 extending along the radial direction of the turntable 2 may be made inside the convex portion 4, instead of the separation gas nozzle 41 (42), and plural holes 40 may be formed along the longitudinal direction of the conduit 47 so that the separation gas (N2 gas) may be ejected from the plural holes 40 in other embodiments.

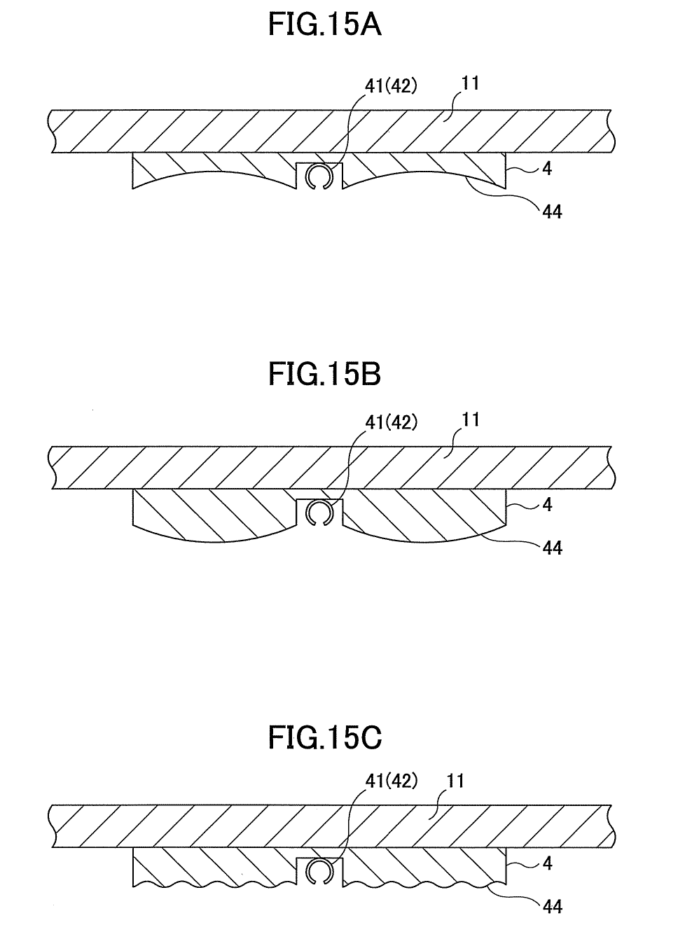

The ceiling surface 44 of the separation area D is not necessarily flat in other embodiments. For example, the ceiling surface 44 may be concavely curved as shown in FIG. 15A, convexly curved as shown in FIG. 15B, or corrugated as shown in FIG. 15C.

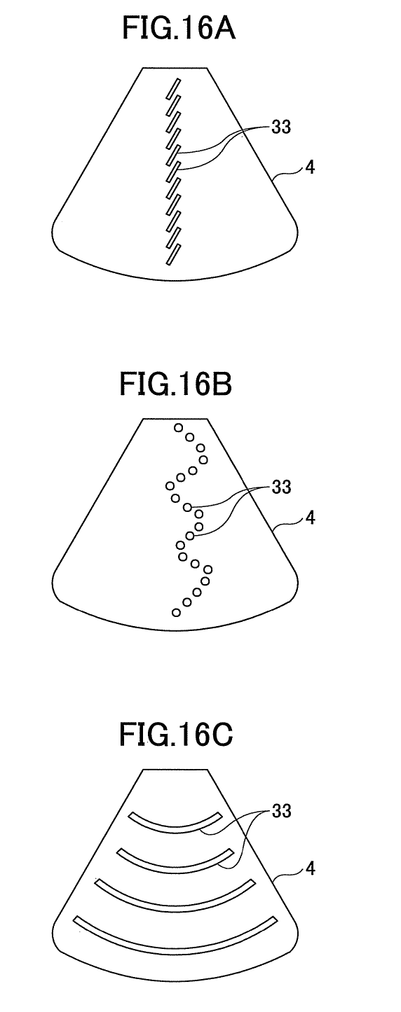

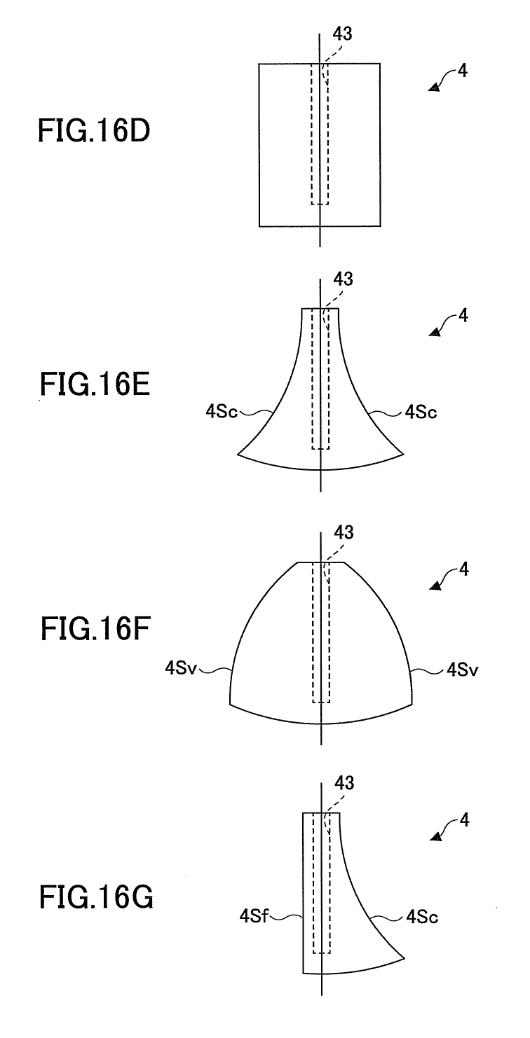

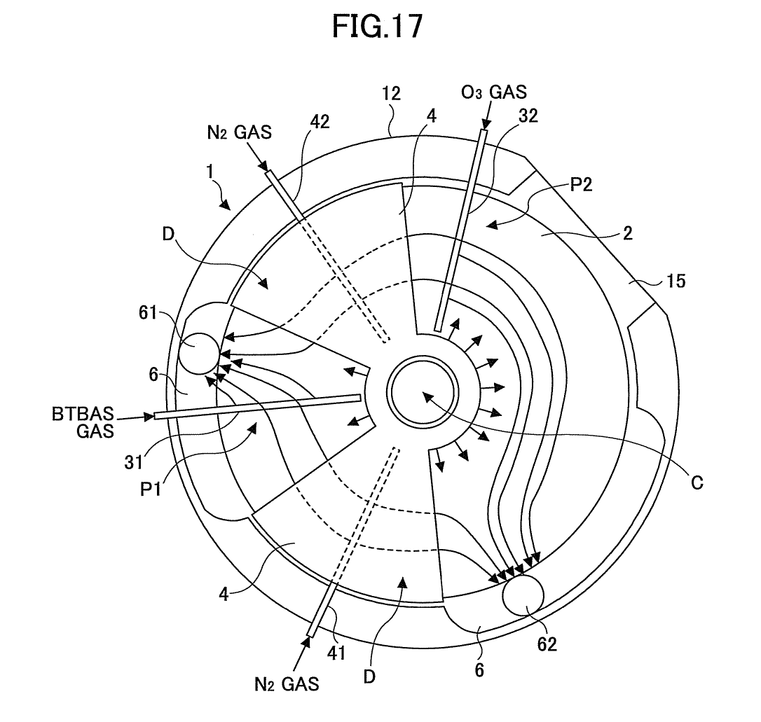

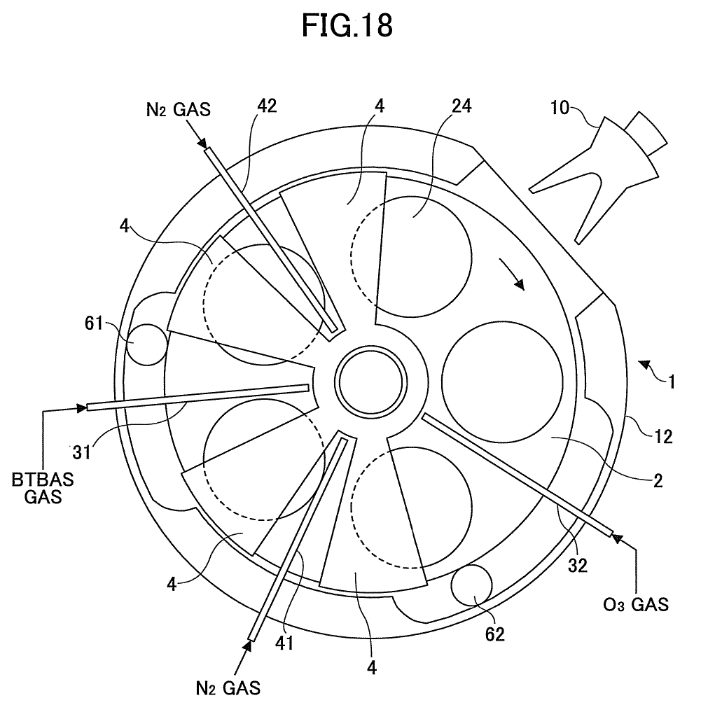

In addition, the convex portion 4 may be hollow and the separation gas may be introduced into the hollow convex portion 4. In this case, the plural gas ejection holes 33 may be arranged as shown in FIGS. 16A, 16B, 16C.

Referring to FIG. 16A, the plural gas ejection holes 33 each have a shape of a slanted slit. These slanted slits (gas ejection holes 33) are arranged to be partially overlapped with an adjacent slit along the radial direction of the turntable 2. In FIG. 16B, the plural gas ejection holes 33 are circular. These circular holes (gas ejection holes 33) are arranged along a serpentine line that extends in the radial direction as a whole. In FIG. 16C, each of the plural gas ejection holes 33 has the shape of an arc-shaped slit. These arc-shaped slits (gas ejection holes 33) are arranged at predetermined intervals in the radial direction.

While the convex portion 4 has the sector-shaped top view shape in this embodiment, the convex portion 4 may have a rectangle top view shape as shown in FIG. 16D, or a square top view shape in other embodiments. Alternatively, the convex portion 4 may be sector-shaped as a whole in the top view and have concavely curved side surfaces 4Sc, as shown in FIG. 16E. In addition, the convex portion 4 may be sector-shaped as a whole in the top view and have convexly curved side surfaces 4Sv, as shown in FIG. 16F. Moreover, an upstream portion of the convex portion 4 relative to the rotation direction of the turntable 2 (FIG. 1) may have a concavely curved side surface 4Sc and a downstream portion of the convex portion 4 relative to the rotation direction of the turntable 2 (FIG. 1) may have a flat side surface 4Sf, as shown in FIG. 16G. Incidentally, dotted lines in FIGS. 16D through 16G represent the groove portions 43. In these cases, the separation gas nozzle 41 (42), which is housed in the groove portion 43, extends from the center portion of the chamber 1, for example, from the protrusion portion 5.

The heater unit 7 for heating the wafers W is configured to have a lamp or radiative heating element instead of the resistance heating element. In addition, the heater unit 7 may be located above the turntable 2, or above and below the turntable 2.

The process areas P1, P2 and the separation area D may be arranged in other embodiments, as shown in FIG. 17. Referring to FIG. 17, the second reaction gas nozzle 32 for supplying the second reaction gas (e.g., O₃ gas) is located upstream of the rotation direction relative to the transfer opening 15, or between the separation gas nozzle 42 and the transfer opening 15. Even in such an arrangement, the gases ejected from the nozzle 31, 32, 41, 42 and the center area C flow generally along arrows shown in FIG. 17, so that the first reaction gas and the second reaction gas cannot be mixed. Therefore, a proper ALD (or MLD) mode film deposition can be realized by such an arrangement.

In addition, the separation area D may be configured by attaching two sector-shaped plates on the bottom surface of the ceiling plate 1 by screws so that the two sector-shaped plates are located on both sides of the separation gas nozzle 41 (42), as stated above. FIG. 18 is a plan view of such a configuration. In this case, the distance between the convex portion 4 and the separation gas nozzle 41 (42), and the size of the convex portion 4 can be determined taking into consideration ejection rates of the separation gas and the reaction gas in order to effectively demonstrate the separation function of the separation area D.

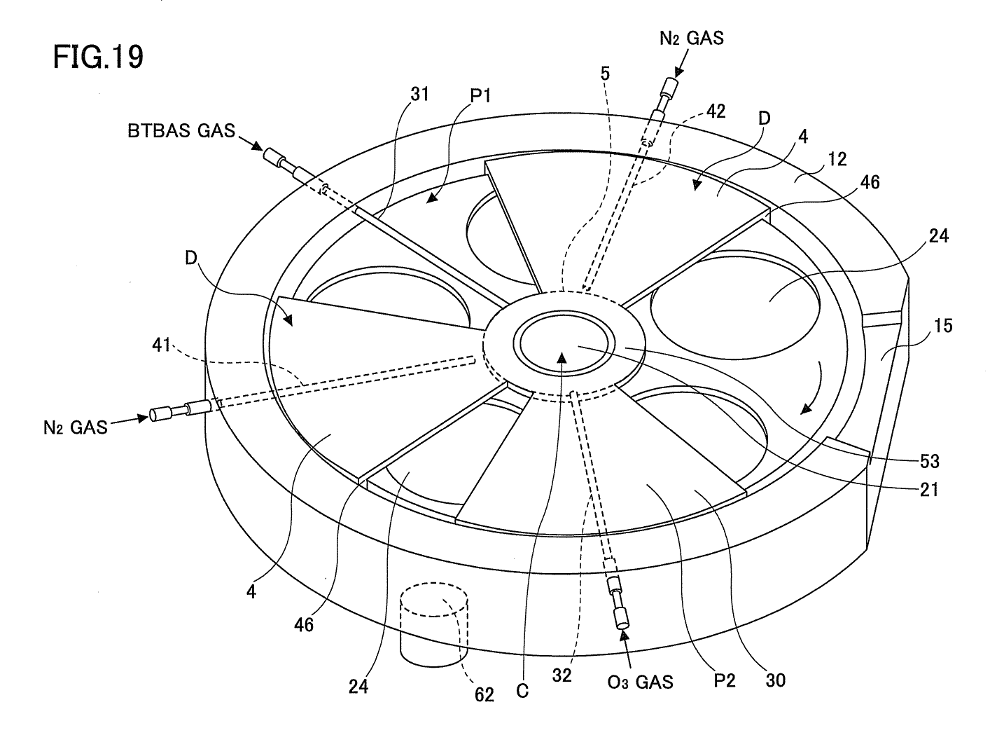

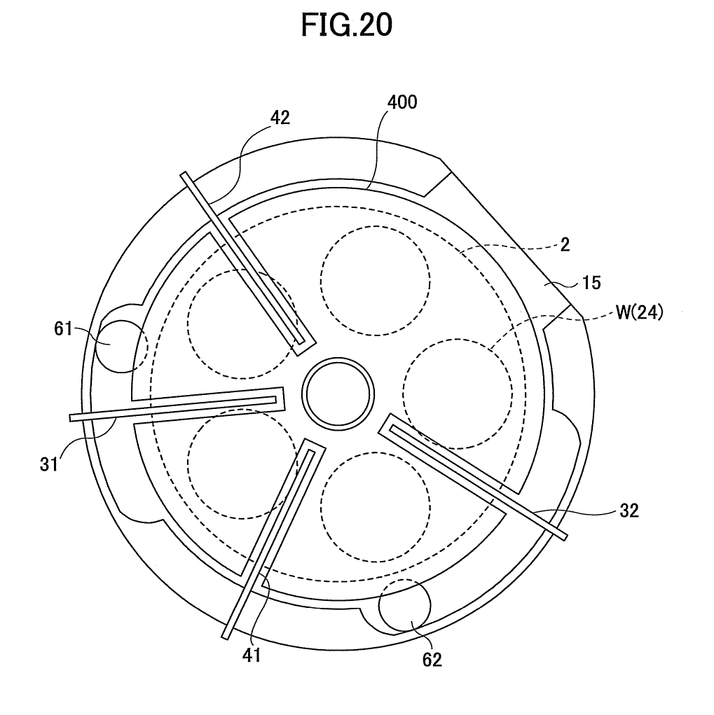

In the above embodiment, the first process area P1 and the second process area P2 correspond to the areas having the ceiling surface 45 higher than the ceiling surface 44 of the separation area D. However, at least one of the first process area P1 and the second process area P2 may have another ceiling surface that opposes the turntable 2 in both sides of the reaction gas supplying nozzle 31 (32) and is lower than the ceiling surface 45 in order to prevent gas from flowing into a gap between the ceiling surface concerned and the turntable 2. This ceiling surface, which is lower than the ceiling surface 45, may be as low as the ceiling surface 44 of the separation area D. FIG. 19 shows an example of such a configuration. As shown, a sector-shaped convex portion 30 is located in the second process area P2, where the O₃ gas is adsorbed on the wafer W, and the reaction gas nozzle 32 is located in the groove portion (not shown) formed in the convex portion 30. In other words, this second process area P2 shown in FIG. 19 is configured in the same manner as the separation area D, while the gas nozzle is used in order to supply the reaction gas. In addition, the convex portion 30 may be configured as a hollow convex portion, example of which is illustrated in FIGS. 16A through 16C.

Moreover, the ceiling surface, which is lower than the ceiling surface 45 and as low as the ceiling surface 44 of the separation area D, may be provided for both reaction gas nozzles 31, 32 and extended to reach the ceiling surfaces 44 in other embodiments as long as the low ceiling surfaces 44 are provided on both sides of the reaction gas nozzle 41 (42) In other words, another convex portion 400 may be attached on the bottom surface of the ceiling plate 11, instead of the convex portion 4. The convex portion 400 has a shape of substantially circular plate, opposes substantially the entire top surface of the turntable 2, has four slots 400a where the corresponding gas nozzles 31, 32, 41, 42 are housed, the slots 400a extending in a radial direction, and leaves a thin space below the convex portion 400 in relation to the turntable 2. A height of the thin space may be comparable with the height h stated above. When the convex portion 400 is employed, the reaction gas ejected from the reaction gas nozzle 31 (32) diffuses to both sides of the reaction gas nozzle 31 (32) below the convex portion 400 (or in the thin space) and the separation gas ejected from the separation gas nozzle 41 (42) diffuses to both sides of the separation gas nozzle 41 (42). The reaction gas and the separation gas flow into each other in the thin space and are evacuated through the evacuation port 61 (62). Even in this case, the reaction gas ejected from the reaction gas nozzle 31 cannot be mixed with the other reaction gas ejected from the reaction gas nozzle 32, thereby realizing a proper ALD (or MLD) mode film deposition.

Incidentally, the convex portion 400 may be configured by combining the hollow convex portions 4 shown in any of FIGS. 16A through 16C in order to eject the reaction gases and the separation gases from the corresponding ejection holes 33 in the corresponding hollow convex portions 4 without using the gas nozzles 31, 32, 41, 42 and the slits 400a.

In the above embodiments, the rotation shaft 22 for rotating the turntable 2 is located in the center portion of the chamber 1. In addition, the space 52 between the core portion 21 and the ceiling plate 11 is purged with the separation gas in order to prevent the reaction gases from being mixed through the center portion. However, the chamber 1 may be configured as shown in FIG. 18 in other embodiments. Referring to FIG. 18, the bottom portion 14 of the chamber body 12 has a center opening to which a housing case 80 is hermetically attached. Additionally, the ceiling plate 11 has a center concave portion 80a. A pillar 81 is placed on the bottom surface of the housing case 80, and a top end portion of the pillar 81 reaches a bottom surface of the center concave portion 80a. The pillar 81 can prevent the first reaction gas (BTBAS) ejected from the first reaction gas nozzle 31 and the second reaction gas (O₃) ejected from the second reaction gas nozzle 32 from being mixed through the center portion of the chamber 1.

In addition, a rotation sleeve 82 is provided so that the rotation sleeve 82 coaxially surrounds the pillar 81. The rotation sleeve 82 is supported by bearings 86, 88 attached on an outer surface of the pillar 81 and a bearing 87 attached on an inner side wall of the housing case 80. Moreover, the rotation sleeve 82 has a gear portion 85 formed or attached on an outer surface of the rotation sleeve 82. Furthermore, an inner circumference of the ring-shaped turntable 2 is attached on the outer surface of the rotation sleeve 82. A driving portion 83 is housed in the housing case 80 and has a gear 84 attached to a shaft extending from the driving portion 83. The gear 84 is meshed with the gear portion 85. With such a configuration, the rotation sleeve 82 and thus the turntable 2 are rotated by a driving portion 83.

A purge gas supplying pipe 74 is connected to an opening formed in a bottom of the housing case 80, so that a purge gas is supplied into the housing case 80. With this, an inner space of the housing case 80 may be kept at a higher pressure than an inner space of the chamber 1, in order to prevent the reaction gases from flowing into the housing case 80. Therefore, no film deposition takes place in the housing case 80, thereby reducing maintenance frequencies. In addition, purge gas supplying pipes 75 are connected to corresponding conduits 75a that reach from an upper outer surface of the chamber 1 to an inner side wall of the concave portion 80a, so that a purge gas is supplied toward an upper end portion of the rotation sleeve 82. Because of the purge gas, the BTBAS gas and the O₃ gas cannot be mixed through a space between the outer surface of the rotation sleeve 82 and the side wall of the concave portion 80a. Although the two purge gas supplying pipes 75 are illustrated in FIG. 18, the number of the pipes 75 and the corresponding conduits 75a may be determined so that the purge gas from the pipes 75 can assuredly avoid gas mixture of the BTBAS gas and the O3 gas in and around the space between the outer surface of the rotation sleeve 82 and the side wall of the concave portion 80a.

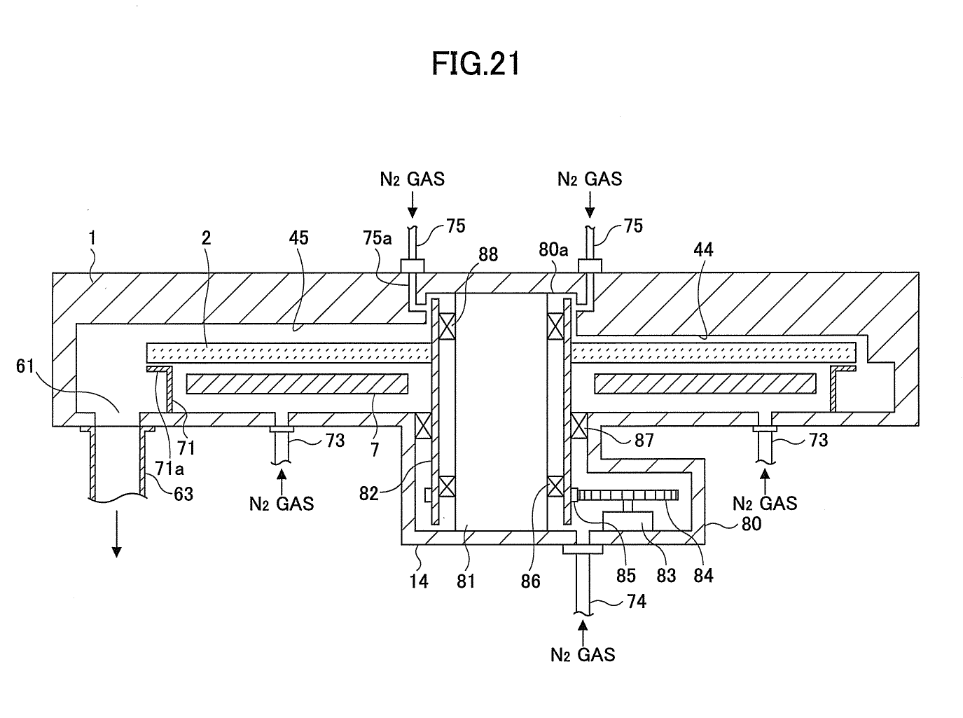

In the embodiment illustrated in FIG. 21, a space between the side wall of the concave portion 80a and the upper end portion of the rotation sleeve 82 corresponds to the ejection hole for ejecting the separation gas. In addition, the center area is configured with the ejection hole, the rotation sleeve 82, and the pillar 81.

A description will now be given of another example of the transfer method of the wafer W.

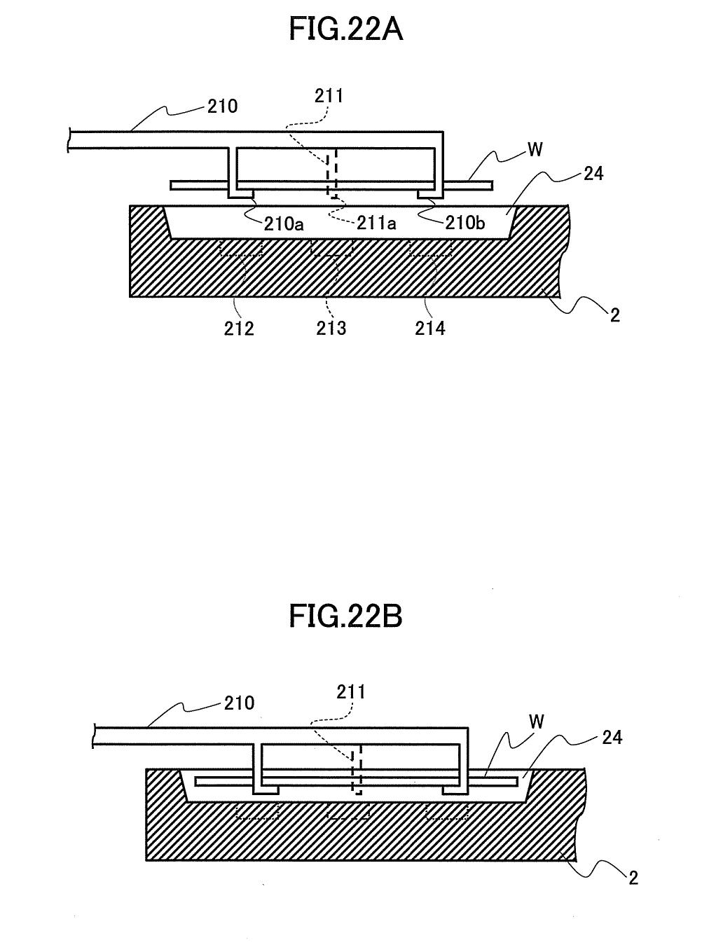

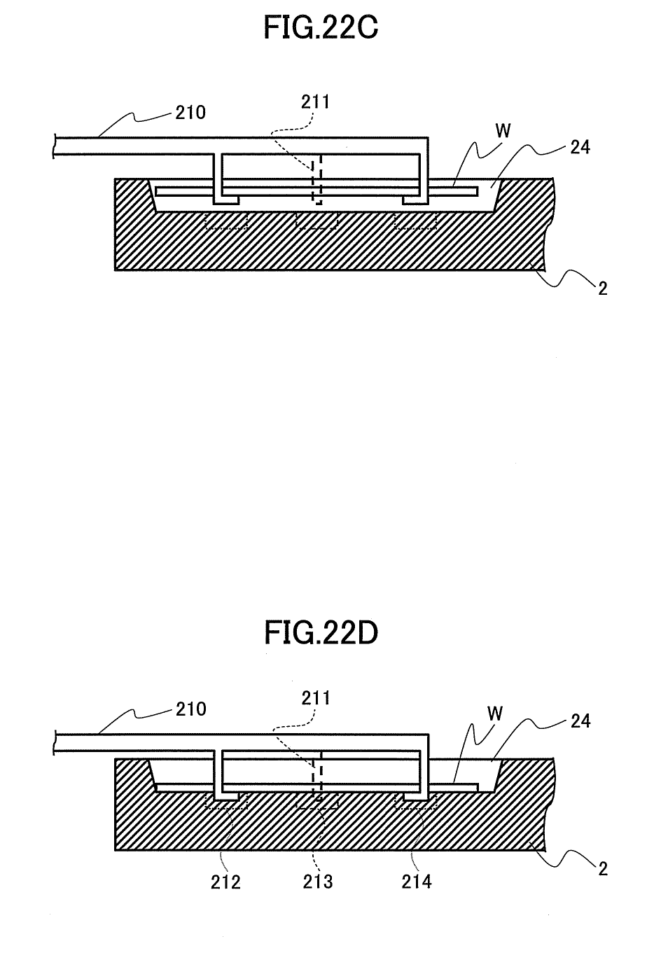

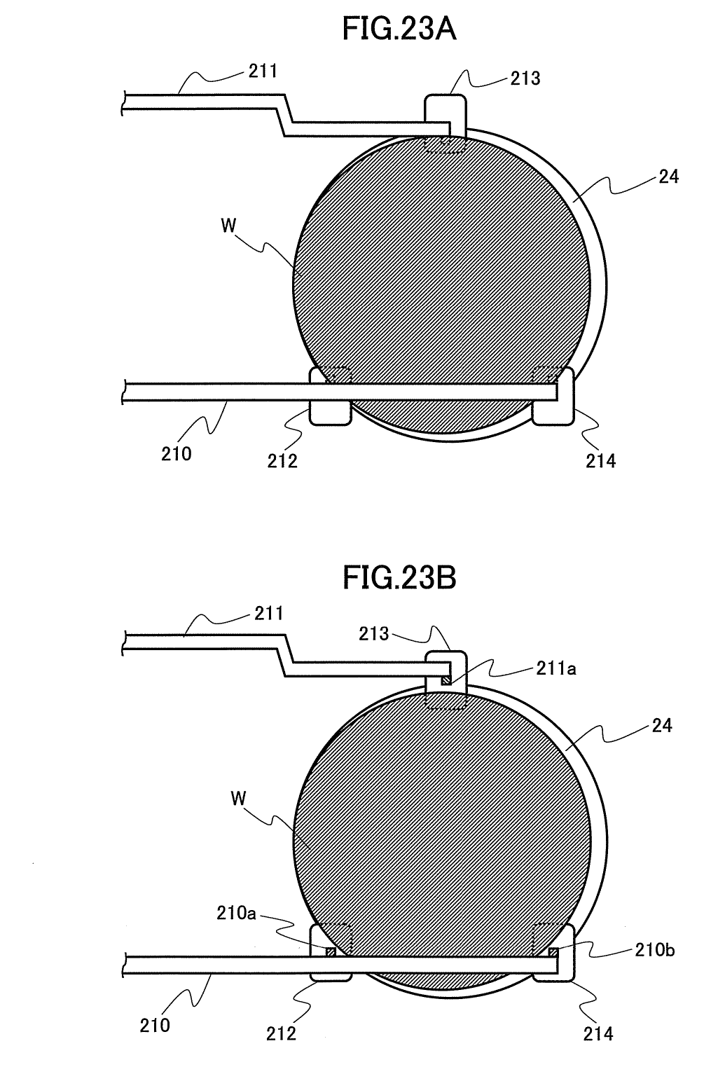

The method explained below is a so-called top-grabbing method, and a specific procedure thereof will be explained with reference to FIGS. 22A through 22D and FIGS. 23A and 23B. Similar to the above-mentioned method, a diameter of the wafer W used in the present embodiment is 300 mm and a diameter of the concave portion 24 is 304 mm. Accordingly, the concave portion 24 is larger than the wafer W by 4 mm.

As illustrated in FIG. 22A, the wafer W is conveyed to a position directly above the concave portion 24 of the turntable 2 by using top-grabbing arms 210 and 211, which are rod-like holding parts forming substrate holding arms. As a procedure of conveyance, similar to the above-mentioned conveyance arm 10, a gate valve, which is not illustrated in the figure, is opened, and the wafer W is moved to a position on the concave portion 24 of the turntable 2 by the top-grabbing arms 210 and 211 through the conveyance port 15. The top-grabbing arm 210 is provided with wafer contact parts 210a and 210b, which form two claw-like substrate holding parts. The top-grabbing arm 211 is provided with a wafer contact part 211a, which forms a claw-like substrate holding part. The wafer W is held by the top-grabbing arms 210 and 211 by bringing the three wafer contact parts 210a, 210b and 211a into contact with the wafer W. The top-grabbing arms 210 and 211 are movable in upward and downward directions and a radial direction of the turntable 2. As mentioned later, an interval between the top-grabbing arms can be decreased or increased in directions perpendicular to the surface of the drawing.

In a circumference portion of the turntable 2, which is an edge part of the concave portion 24, concave portions 212, 213 and 214 having a sufficient depth are provided so that wafer contact parts 210a, 210b and 211 do not contact the turntable 2 when placing the wafer W on the bottom part of the concave portion 24 of the turntable 2. The arm concave portions 212, 213 and 214 are deeper than the concave portion 24.

Then, as illustrated in FIG. 22B, the water W is moved downward by entirely moving the top-grabbing arms 210 and 211 downward until the wafer W enters the concave portion 24, and thereafter the downward movement of the wafer W is stopped (first downward moving process). In this state, the surface of the wafer W is at a position lower than the surface of the turntable 2.

Then, as illustrated in FIG. 22C, the top-grabbing arms 210 and 211 are moved in a radial direction (in a leftward direction in the figure) until the wafer W moves to a position at which the circumferential part of the wafer W contacts or moves to a position close to the wall surface of the concave portion 24 of the turntable 2. A portion of the concave portion 24 in contact with or close to the circumference of the wafer W is a portion of the wall surface of the concave portion 24, which is most distant from the center of the turntable 2. The movement of the wafer W is achieved by entirely moving the top-grabbing arms 210 and 211 in a radially outward direction of the turntable 2. There may be a case in which the wall surface of the concave portion 24 of the turntable 2 is tapered. In such a case, it is desirable to move the wafer W to a predetermined position close to the wall surface rather than bringing the wafer W into contact with the wall surface of the concave portion 24.

Thereafter, as illustrated in FIG. 22D, the top-grabbing arms 210 and 210 are further moved downward (second downward moving process). Specifically, the wafer W is moved downward until the wafer W is brought into contact with the bottom part of the concave portion 24 of the turntable 2. In this state, the wafer contact parts 212, 213 and 214 do not contact the turntable 2 because the arm concave portions are [???] sufficiently deep.

FIG. 23A illustrates the top surface of the turntable 2 in this state. The wafer W is in contact with or close to the wall surface of the concave portion 24 of the turntable 2 at a circumference part of the wafer in a radial direction of the turntable 2.

Thereafter, as illustrated in FIG. 23B, after slightly moving the top-grabbing arms 210 and 211 in a downward direction, the interval between the top-grabbing arms 210 and 211 is increased. Specifically, the top-grabbing arm 210 is moved upward with respect to the drawing surface and the top-grabbing arm 211 is moved downward with respect to the drawing surface to expand the interval of the top-grabbing arms 210 and 211 and move the wafer contract parts 210a, 210b and 211a to positions sufficiently apart from the wafer W.

Then, after moving the top-grabbing arms 210 and 211 upward, the top-grabbing arms 210 and 211 are moved in a radially outward direction (a leftward direction) and placement of the wafer W is completed.

In the above-mentioned embodiment, there is no need to provide the elevation pins 16. Because the wafer W is in contact with or close to the wall surface of the concave portion 24 of the turntable 2 in the circumference thereof in a radial direction of the turntable 2, even if the turntable 2 rotates at a high speed, the wafer W does not forcefully hit the wall surface of the concave portion 24 of the turntable 2 due to a centrifugal force. Accordingly, there is little possibility of generation of cracking or chipping of the wafer W. Thus, generation of particles due to a contact of the wafer W with the wall surface of the concave portion 24 of the turntable 2 is prevented, and an environmental pollution inside the apparatus and incorporation of foreign matters into a deposited film can be prevented.

In the present embodiment, although the wafer contact parts 210a, 210b and 211a are provided at three positions of the top-grabbing arms 210 and 211, respectively, the wafer contact parts may be provided at four or more positions.

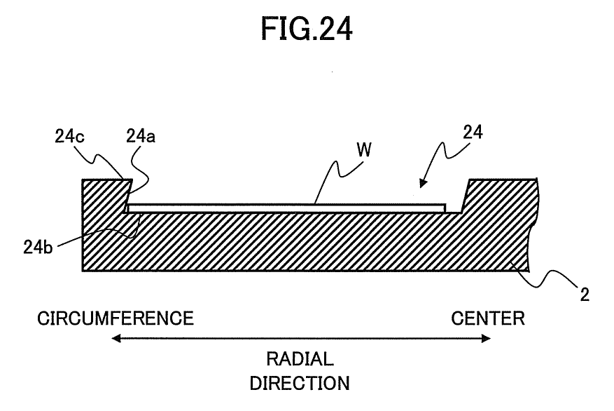

As illustrated in FIG. 24, in the present embodiment, the concave portion 24 of the turntable 2 in the film deposition apparatus may be configured so that an upper part 24c of the wall surface of the concave portion 24 on the circumferential side of the turntable 2 overhangs with respect to a bottom part 24b of the wall surface of the concave portion 24. According to this configuration, the wafer W is prevented from flying out of the concave portion 24 due to a centrifugal force when the turntable 2 is rotated. This structure of the concave portion 24 serving as a substrate placement part is applicable to the turntable 2 in all of the above-mentioned embodiments.

Although the two kinds of reaction gases are used in the film deposition apparatus according to the above embodiment, three or more kinds of reaction gases may be used in other film deposition apparatus according to other embodiments of the present invention. In this case, a first reaction gas nozzle, a separation gas nozzle, a second reaction gas nozzle, a separation gas nozzle, and a third reaction gas nozzle may be located in this order at predetermined angular intervals, each nozzle extending along the radial direction of the turntable 2.

Additionally, the separation areas D including the corresponding separation gas nozzles are configured in the same manner as explained above.

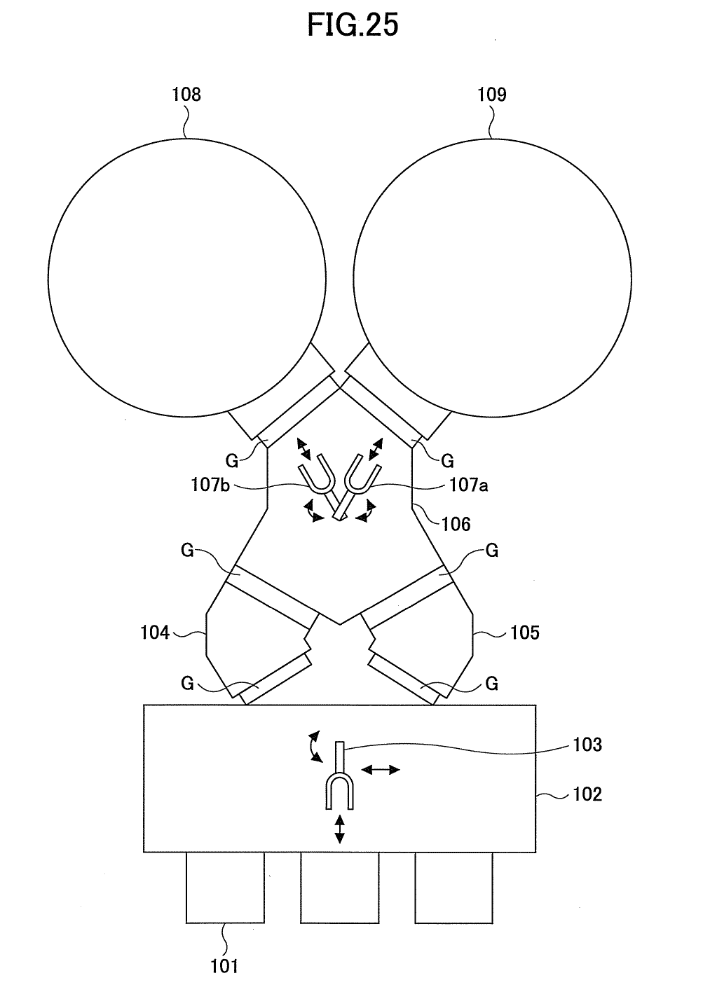

The film deposition apparatus according to embodiments of the present invention may be integrated into a wafer process apparatus, an example of which is schematically illustrated in FIG. 25. The wafer process apparatus includes an atmospheric transfer chamber 102 in which a transfer arm 103 is provided, a load lock chamber (preliminary vacuum chamber) 105 whose atmosphere is changeable between vacuum and atmospheric pressure, a vacuum transfer chamber 106 in which two transfer arms 107a, 107b are provided, and film deposition apparatuses 108, 109 according to embodiments of the present invention. In addition, the wafer process apparatus includes cassette stages (not shown) on which a wafer cassette 101 such as a Front Opening Unified Pod (FOUP) is placed. The wafer cassette 101 is brought onto one of the cassette stages, and connected to a transfer in/out port provided between the cassette stage and the atmospheric transfer chamber 102. Then, a lid of the wafer cassette (FOUP) 101 is opened by an opening/closing mechanism (not shown) and the wafer is taken out from the wafer cassette 101 by the transfer arm 103. Next, the wafer is transferred to the load lock chamber 104 (105). After the load lock chamber 104 (105) is evacuated, the wafer in the load lock chamber 104 (105) is transferred further to one of the film deposition apparatuses 108, 109 through the vacuum transfer chamber 106 by the transfer arm 107a (107b). In the film deposition apparatus 108 (109), a film is deposited on the wafer in such a manner as described above. Because the wafer process apparatus has two film deposition apparatuses 108, 109 that can house five wafers at a time, the ALD (or MLD) mode deposition can be performed at high throughput.

The present invention is not limited to the specifically disclosed embodiments, and variations and modifications may be made without departing from the scope of the present invention.

What is claimed is:

1. A film deposition apparatus for depositing a film on a substrate by carrying out a cycle of alternately supplying at least two kinds of reaction gases that react with each other to the substrate to produce a layer of a reaction product in a chamber, the film deposition apparatus comprising:
a turntable rotatably provided in said chamber;
a substrate placement part provided in one surface of said turntable and configured to place said substrate thereon;
a first reaction gas supplying portion configured to supply a first reaction gas to said one surface;
a second reaction gas supplying portion configured to supply a second reaction gas to said one surface, the second reaction gas supplying portion being separated from said first reaction gas supplying portion along a rotation direction of said turntable;
a separation area located along the rotation direction between a first process area to which the first reaction gas is supplied and a second process area to which the second reaction gas is supplied, the separation area separating said first process area and said second process area from each other;
a center area that is located substantially in a center portion of said chamber in order to separate said first process area and said second process area, and has an discharge hole that discharges a first separation gas along said one surface; and
an evacuation port provided configured and arranged to exhaust said first and second reaction gases together with the separation gas diffusing both sides of said separation area and the separation gas discharged from said center portion;
a separation gas supplying portion provided in said separation area to supply the separation gas;
a ceiling surface provided in said separation area and located on both sides of said separation gas supplying portion, the ceiling surface forming a thin space between said turntable to allow the separation gas flowing from the separation area to a process area side; and
an elevation mechanism provided in said substrate placement part to move said substrate upward and downward,
wherein said elevation mechanism is movable upward and downward relative to said turntable and also movable in a radial direction of said turntable.

2. The film deposition apparatus as claimed in claim 1, wherein said elevation mechanism includes at least three lift pins.

3. The film deposition apparatus as claimed in claim 1, further comprising:
a ceiling plate provided in the separation area to which the first separation gas is supplied by said separation gas supplying portion, the ceiling plate facing a surface of said turntable on which said substrate placement part is formed;
a second separation gas supplying portion configured to supply a second separation to separate said first reaction gas and said second reaction gas from a center area of said turntable; and
an evacuation port provided at a position lower than said turntable to exhaust said first reaction gas, said second reaction gas, said first separation gas and said second separation gas through a gap between a circumferential edge of said turntable and an inner wall of said chamber.

4. The film deposition apparatus as claimed in claim 1, further comprising a rotating mechanism to rotate said turntable during a film deposition.

5. The film deposition apparatus as claimed in claim 1, wherein said substrate placement part is formed as a concave portion on a surface of said turntable, and a surface of said substrate placed on said substrate placement part are at the same height, or the surface of said substrate is lower than the surface of said turntable.

6. The film deposition apparatus as claimed in claim 5, wherein the concave portion of said substrate placement part has an upper portion overhanging with respect to a bottom surface of said concave portion in a direction opposite to a circumferential edge of said turntable on a side of the circumferential edge of said turntable.

7. The film deposition apparatus as claimed in claim 1, wherein a conveyance port is provided on a side wall of said chamber to convey said substrate from an outside of said chamber into an inside of said chamber, the conveyance port being opened and closed by a gate valve.

8. The film deposition apparatus as claimed in claim 7, further comprising a conveyance arm to perform a conveyance of said substrate through said conveyance port.

9. The film deposition apparatus as claimed in claim 2, wherein said substrate is placed at a position most apart from a center of said turntable in said substrate placement part of said turntable by moving said lift pins in a radial direction of said turntable.

10. A film deposition apparatus for depositing a film on a substrate by carrying out a cycle of alternately supplying at least two kinds of reaction gases that react with each other to the substrate to produce a layer of a reaction product in a chamber, the film deposition apparatus comprising:
a turntable rotatably provided in said chamber;
a plurality of substrate placement parts provided in said turntable to place a plurality of pieces of said substrate along the same circumference of said turntable;
a first reaction gas supplying portion configured to supply a first reaction gas, the first reaction gas provided on a side where said substrate placement parts are formed in said chamber;
a second reaction gas supplying portion configured to supply a second reaction gas supplying portion, the second reaction gas supplying portion provided at a position distant from said first reaction gas supplying portion on the side where said substrate placement parts are formed in said chamber;
a first separation gas supplying portion configured to supply a first separation gas, the first separation gas supplying portion provided between a first process area to which the first reaction gas is supplied by said first reaction gas supplying portion and a second process area to which the second reaction gas is supplied by said second reaction gas supplying portion to separate said first process area and said second process area from each other;
a conveyance port provided on a side wall of said chamber to convey said substrate from an outside of said chamber into an inside of said chamber, the conveyance port being opened and closed by a gate valve; and
a substrate holding arm for conveying said substrate through said conveyance port,
wherein said substrate holding arm includes two rod-shaped holding parts, one of the rod-shaped holding parts being provided with at least one substrate holding portion and the other of the rod-shaped holding parts being provided with at least two substrate holding portions to hold said substrate.

11. The film deposition apparatus as claimed in claim 10, further comprising:
a ceiling plate provided in a separation area to which the first separation gas is supplied by said separation gas supplying portion, the ceiling plate facing a surface of said turntable on which said substrate placement parts are formed;
a second separation gas supplying portion configured to supply a second separation gas to separate said first reaction gas and said second reaction gas from a center area of said turntable; and
an evacuation port provided at a position lower than said turntable to exhaust said first reaction gas, said second reaction gas, said first separation gas and said second separation gas through a gap between a circumferential edge of said turntable and an inner wall of said chamber.

12. The film deposition apparatus as claimed in claim 10, further comprising a mechanism configured to change an interval between said two rod-shaped holding parts of said substrate holding arm.

13. The film deposition apparatus as claimed in claim 10, wherein each of said substrate holding portions has a claw portion, and a concave area deeper than said substrate placement part is provided with respect to said claw portion in an edge portions of said substrate placement part.

14. The film deposition apparatus as claimed in claim 10, further comprising a rotating mechanism to rotate said turntable during a film deposition.

15. The film deposition apparatus as claimed in claim 1, wherein said substrate placement parts are formed as concave portions on a surface of said turntable, and a surface of said substrate placed on each of said substrate placement parts is at the same height, or the surface of said substrate is lower than the surface of said turntable.

16. The film deposition apparatus as claimed n claim 15, wherein each of the concave portions of said substrate placement parts has an upper portion overhanging with respect to a bottom surface of said concave portion in a direction opposite to a circumferential edge of said turntable on a side of the circumferential edge of said turntable.

17. The film deposition apparatus as claimed in claim 10, wherein said substrate holding arm places said substrate at a position most apart from a center of said turntable in each of said substrate placement parts of said turntable by moving in a radial direction of said turntable.

18. A substrate processing apparatus comprising:
a vacuum transfer chamber in which a substrate transfer part is arranged;
the film deposition apparatus according to claim 1 connected airtightly to said vacuum transfer chamber; and
a preliminary vacuum chamber airtightly connected to said vacuum transfer chamber, a pressure inside said preliminary vacuum chamber being changed between an atmospheric pressure and a vacuum pressure.

19. A substrate processing apparatus comprising:
a vacuum transfer chamber in which a substrate transfer part is arranged;
the film deposition apparatus according to claim 10 connected airtightly to said vacuum transfer chamber; and
a preliminary vacuum chamber airtightly connected to said vacuum transfer chamber, a pressure inside said preliminary vacuum chamber being changed between an atmospheric pressure and a vacuum pressure.

20. A film deposition method for forming a film on a substrate by carrying out a plurality of cycles of sequentially supplying at least two kinds of reaction gases that react with each other to a surface of said substrate:
conveying said substrate from an outside of a vacuum chamber through a conveyance port, and placing said substrate at a position most apart from a center of said turntable in a substrate placement part provided for placing said substrate on said turntable of said vacuum chamber;
rotating said turntable; and
depositing said film on said substrate by supplying first and second reaction gases to a surface of said turntable in which a substrate placement part is formed from a first reaction gas supplying portion and a second reaction gas supplying portion provided separate from each other in said vacuum chamber, and supplying a separation gas from a separation gas supplying portion provided between said first reaction gas supplying portion and said second reaction gas supplying portion.

21. A film deposition method for forming a film on a substrate by carrying out a plurality of cycles of sequentially supplying at least two kinds of reaction gases that react with each other to a surface of said substrate:
placing said substrate on an elevation mechanism provided in a substrate placement part formed as a concave portion on a turntable, said substrate being conveyed from an outside of a vacuum chamber into an inside of said vacuum chamber through a conveyance port;
after moving said substrate into the concave portion, causing said substrate to contact or move to a position close to a wall surface of said concave portion by moving said elevation mechanism in a radial direction of said turntable;
after moving said elevation mechanism in a radial direction of said turntable, moving said elevation mechanism downward and placing said substrate on a bottom surface of said concave portion;
after placing said substrate on a bottom surface of said concave portion, rotating said turntable; and
depositing said film on said substrate by supplying first and second reaction gases to a surface of said turntable in which the substrate placement part is formed from first and second reaction gas supplying portions provided separate from each other in said vacuum chamber, and supplying a separation gas from a separation gas supplying portion provided between said first reaction gas supplying portion and said second reaction gas supplying portion.

22. A film deposition method for forming a film on a substrate by carrying out a plurality of cycles of sequentially supplying at least two kinds of reaction gases that react with each other to a surface of said substrate:
conveying said substrate to a position directly above a substrate placement part formed on a turntable as a concave portion to place said substrate thereon by a substrate holding arm having two rod-shaped holding parts for holding said substrate, one of the rod-shaped holding parts having at least one substrate holding portion and the other of the rod-shaped holding parts having at least two substrate holding portions;
after conveying said substrate to a position directly above said substrate placement part, moving said substrate to a position lower than a surface of said turntable by moving said substrate holding arm downward;
after moving said substrate holding arm downward, causing said substrate to contact or move to a position close to a wall surface of said concave portion by moving said substrate holding arm in a radially outward direction of said turntable;
after causing said substrate to contact or move to a position close to a wall surface of said concave portion, moving said substrate holding arm downward until said substrate contacts a bottom surface of said concave portion;
after moving said substrate holding arm downward, rotating said turntable; and
depositing said film on said substrate by supplying first and second reaction gases to a surface of said turntable in which the substrate placement part is formed from first and second reaction gas supplying portions provided separate from each other in said vacuum chamber, and supplying a separation gas from a separation gas supplying portion provided between said first reaction gas supplying portion and said second reaction gas supplying portion.

23. A computer readable storage medium storing a program for causing a computer to perform the film deposition method as claimed in claim 20.

24. A computer readable storage medium storing a program for causing a computer to perform the film deposition method as claimed in claim 21.

25. A computer readable storage medium storing a program for causing a computer to perform the film deposition method as claimed in claim 22.
